(19) United States
(12) Patent Application Publication
(10) Pub. No.: US 2023/0103467 A1
(43) Pub. Date: Apr. 6, 2023

(54) NON-INVASIVE CONTINUOUS CAPACITANCE LEVEL DETECTOR

(71) Applicant: Merck Sharp & Dohme LLC, Rahway, NJ (US)

(72) Inventors: William Blincoe, Fords, NJ (US); Michael Yves Louge, Ithaca, NY (US); Jasdeep Mandur, Lansdale, PA (US); Anthony S. Tantuccio, Downingtown, PA (US)

(73) Assignee: Merck Sharp & Dohme LLC, Rahway, NJ (US)

(21) Appl. No.: 17/785,750

(22) PCT Filed: Dec. 11, 2020
(86) PCT No.: PCT/US2020/064440

§ 371 Date: Jun. 15, 2022

Related U.S. Application Data
(60) Provisional application No. 62/949,172, filed on Dec. 17, 2019.
(60) Provisional application No. 63/067,644, filed on Aug. 19, 2020.

(51) Int. Cl. G01F 23/263; G01R 27/26

(52) U.S. Cl. CPC G01F 23/268; G01R 27/2623

(57) ABSTRACT

The present invention relates to a non-invasive Capacitance Level Detector useful for continuous detection of the level and/or mass of a non-conductive or weakly-conductive bulk material in a vessel, and methods of using the detector.

### FIELD OF THE INVENTION

The present invention relates to a non-invasive Capacitance Level Detector useful for continuous detection of the level and/or mass of a non-conductive or weakly-conductive bulk material in a vessel, and methods of using the detector.

### BACKGROUND OF THE INVENTION

The reproducible processing of pharmaceutical materials requires an accurate determination of their amount stored in tubes and hoppers. Capacitive level detectors are very good for a wide variety of applications as they can be used to measure dielectric liquids, powders, and bulk solids. This type of detector can be installed in various types of vessels and the probe can typically be shortened or lengthened to accommodate the necessary measurement. Capacitive level detectors determine the level of material by measuring changes in probe capacitance resulting from the displacement of dielectric materials between the probe and the reference ground, such as a vessel wall. As material height increases and comes in contact with the probe, the capacitance changes from the normal calibrated state, and the detector actuates. When the material level decreases, the probe again senses the capacitive change, and the detector reverts to its normal state.

Capacitive-type sensors for measuring the level of fluids have been previously described. U.S. Pat. No. 4,176,553 describes a capacitive sensor for sensing the level of fuel in an automotive fuel tank. U.S. Pat. No. 5,103,368 describes a capacitive fluid level sensor which senses fluid levels by charging a plurality of capacitors in sequence.

There remains a need for detectors that can continuously, non-invasively and consistently measure the level of a dielectric liquid or solid in a vessel with a high degree of accuracy regardless of dielectric changes which may occur in the liquid or bulk suspension due to a variety of factors. The present invention addresses that need.

### SUMMARY OF THE INVENTION

In one aspect, the present invention provides a detector (the “Capacitance Level Detector”) useful for the continuous and non-invasive measurement of the level and/or mass of a non-conductive or weakly-conductive bulk material in a vessel, while said bulk material is inside the vessel, and wherein the measurement is taken inside the vessel, and wherein the instrument produces level and/or mass as continuous functions of time and amount of said bulk material inside the vessel.

The Capacitance Level Detector can be useful, for example, for the continuous measurement of a powder or fluid as it passes through a storage vessel or a mixing vessel.

Accordingly, the present invention provides methods for the continuous and non-invasive measurement of the level and/or mass of a non-conductive or weakly-conductive bulk material in a vessel.

The details of the invention are set forth in the accompanying detailed description below.

Although any methods and materials similar to those described herein can be used in the practice or testing of the present invention, illustrative methods and materials are now described. Other embodiments, aspects and features of the present invention are either further described in or will be apparent from the ensuing description, examples and appended claims.

### BRIEF DESCRIPTION OF THE DRAWINGS

FIG. 1(a) shows two parallel plate capacitors (1) of area A and unit normal \hat{n} separated by a medium of effective dielectric constant ϵₑ and a distance d establish equal and opposite surface change densities ±σₛ and total surface charge ± [symbol] ₛ=±∫_{A}σₛdA in response to their voltage difference (Vs−V₀). FIG. 1(b) illustrates the equivalent steady conduction heat transfer problem, with two isotherms at Ts and T₀ establishing a heat flux q″ with surface magnitude qₛ″ across a medium of effective conduction kₑ. In general, if the conduction or the electrostatic problem are solved, then capacitance can be derived from either [symbol] =C/ϵₑ=[1/ϵₑ(Vs−V₀)]∫_{A}σₛdA=[1/kₑ(Ts−T₀)]∫_{A} q″dA.

FIG. 2 shows a generic sketch of commercially-available processing electronics (inside the dotted lines), joined to the sensor of a Capacitance Level Detector. In this design, a generic sensor (7) with impedance Z to ground (8) receives an alternating current i with amplitude maintained constant by stabilizing the ac voltage (υₛ−υ₁) around the reference impedance Zᵣ≡m−in. This feedback control uses an op amp (2) of high gain H>>1 fed with a sinusoidal voltage υr. A buffer amplifier (3) of unit gain but high input impedance samples the resulting voltage υs without drawing a significant current. By keeping guard and sensor voltages equal, stray and cable capacitance are eliminated, and the electric field emanating from the sensor is precisely confined. Such electronics, combined with the use of a rectifier (4) produces a rectified voltage \tilde{V} directly proportional to the modulus of Z. Therefore, if Z is purely capacitive, \tilde{V} is inversely proportional to capacitance. If not, the phase between oscillator (5) and guard can be used to extract both the real and imaginary parts of Z from Equations (7)-(10) or, equivalently, its capacitive and conductive components. All components within the dashed line, except the oscillator (5) are called the ‘preamp.’ A typical system includes a single clock feeding several preamps operating at a single frequency on the order of tens of kHz. (6) denotes the reference impedance Zr in the processing electronics, (9) denotes the guard of the Capacitance Level Detector, and (10) denotes the coaxial cable used to join the sensor of the Capacitance Level Detector to the processing electronics

FIG. 3 shows K′e−1 (top plotted curve) and K″e (bottom plotted curve) vs. relative humidity at 25° C. recorded in microcrystalline cellulose (MCC) with a capacitance probe at a bulk density ρ≃0.36 g/cm³ with a PC-201-ATT preamp in a Capacitec 4100-C rack operating at f≃15.63 kHz, n/m=0.034 and nH≃980 MΩ. The x-axis represents relative humidity at 25° C. and the y-axis is dimensionless.

FIG. 4 shows a dimensionless complex plane representing a cross sectional slice of a circular tube (black circle). In this arbitrary example, the measurement volume is bound by field lines emanating from the sensor (13) with α from α₂=□/16 rad (dashed circular arc) to α₁=□/8 rad (solid circular arc). Singularities are solid dots at ±α₀=□□/4 rad. They separate the guard surface (12) and (14) within −α₀<α<α₂ and α₁<α<+α₀ from the ground (11) within +α₀<α<2□−α₀.

FIG. 5(a) shows a sketch of a prototype cylindrical Capacitance Level Detector showing the position of the sensor (15) and guard (16), wherein δ represents the angular sector of the sensor. FIG. 5(b) shows a sketch of the prototype cylindrical Capacitance Level Detector partially filled with a powder (shaded area of tube). FIG. 5(c) shows a top view of the Capacitance Level Detector, with the positions of the sensor (15), guard (16), and ground (17) denoted.

FIG. 6 shows the measurement volume of the reference probe in a circular tube. FIG. 6(a) shows field and equipotential lines, wherein dashed lines bound the field emanating from the sensor (20), and B is the farthest distance between wall and anyone of these lines. Color shading shows the magnitude of the electric field E relative to its value E₀ at [x; y]=[R, 0]. The sensor (20) (−αₛ<α<+αₛ), guard (19) and (21) (−α_{g}<α<−αₛ and +αₛ<α<+α_{g}), and ground (18) (α_{g}<α<2□−α_{g}) sectors are each identified. FIG. 6(b) shows relative field strength E/E₀ (y-axis) vs. relative distance x/R (x-axis). In this design α_{g}≃26° and αₛ≃5.2°.

FIG. 7. K′e−1 (top plotted line) and K″e (bottom plotted line) of microcrystalline cellulose (MCC) at RH≃76% and 21° measured in a press vs. bulk density.

FIG. 8. Shows different views of an instrumented prototype cylindrical Capacitance Level Detector. Diagram A is a vertical cross-section showing the hemi-cylindrical guard (22) and thin sensor (23), and a cut-through of the boss of the adapter (26) that connects the sensor and guard of the reference probe to the processing electronics; diagram B illustrates the position of an additional port (24) for near-infrared (NIR) measurements (this NIR port was not used in the exemplary prototype cylindrical Capacitance Level Detector described herein); diagram C shows the position of the reference probe guard (27) and sensor (28) of the reference probe, and a cross-section a second adapter (25) that connects the sensor and guard of the reference probe to the processing electronics; diagram D is a 180 degree perspective of diagram C showing the outer surface of the boss of adapter 25; and diagram E is an photograph of a fully built prototype cylindrical Capacitance Level Detector. Shown in said photograph are the adapter that connects the processing electronics to the sensor and guard of the level detector (affixed to upper right section of the prototype cylindrical Capacitance Level Detector); NIR port (affixed to lower front of the prototype cylindrical Capacitance Level Detector): and the adapter that connects the processing electronics to the sensor and guard of the reference probe (affixed to the lower left rear of the prototype cylindrical Capacitance Level Detector).

FIG. 9 shows a sketch of a tablet-making process that employs a Capacitance Level Detector. Depicted are the screw-feeders of active pharmaceutical ingredients (30), excipients (31) and lubricant(s) (32), wherein each feeder is moved by its own individually-controlled motor (29). The tablet materials are fed into a blender (33) discharging into the prototype cylindrical Capacitance Level Detector (34) while the blended materials (in powder form) are en route to the tablet press (38). Dotted box 37 diagrams the control system of the processing electronics that receive input (35) from the Capacitance Level Detector, as said powdered blended material flows through the Capacitance Level Detector. Said blended powder has inlet mass flow rate Min and outlet tablet output moue. To illustrate the control system, the dashed rectangle contains Laplace-transformed excursions from steady state values of mass flow rates (\dot{M}ₙ and \dot{M}ₒᵤₜ), powder height ( [symbol] p), and the control of press rotation rate ( [symbol] ) using output (36) from the processing electronics. The negative feedback of the difference between [symbol] p and its set point [symbol] ₛₑₜ controls [symbol] .

FIG. 10 illustrates a typical control sequence during the processing of a powdered substance into a tablet press, as described in FIG. 9. Time-histories (sec); from top to bottom: FIG. 10(a) shows the readout of the relative filling level h*, as provided by the sensor, wherein the x-axis represents time in seconds, and the y-axis represents the relative height of the powder contents of the Capacitance Level Detector relative to the total height of the Capacitance Level Detector; FIG. 10(b) shows the speed of the tablet press during the processing of a powder through the Capacitance Level Detector, as described by FIG. 9, wherein the x-axis represents time in seconds, and the y-axis represents the speed of the tablet press in RPM; FIG. 10(c) shows the raw signal from the sensor during the processing, wherein the x-axis represents time in seconds, and the y-axis represents rectified level sensor voltage \tilde{V}ₗₑᵥₑₗ (V); and FIG. 10(d) shows the effective dielectric constant modulus |Ke| recorded by the reference probe during the processing, wherein the x-axis represents time in seconds, and the y-axis is dimensionless and represents the ratio of the dielectric constant of the material being processed to the dielectric constant of air. The circled numbers in the figures represent consecutive events as follows: (1) feeder is turned on, gradually accumulating powder in the Capacitance Level Detector, first immersing the reference probe, and eventually reaching above the level sensor, pegging h* to 1; (2) tablet press is turned on, causing visible but small variations in |Ke|; (3) press speed is gradually increased, thereby depleting powder in the Capacitance Level Detector; (4) feedback control is started with h* set point shown as a dashed line; (5) blend composition is changed; (6) the control system maintains level constant; (7) the reference probe records a change in effective dielectric constant due to upstream blend changes; (8) control and feed are stopped, so the tube eventually empties (9); (10) feed is restarted; (11) control is restarted to the set point shown; (12) original blend is restored, eventually returning modulus to the h*=2.1 baseline (13). Here, level detector and reference probe were connected to two pre-amps of Capacitec 200-C processing electronics with nH≃610 M□ and m/n≃0.00139 sharing the same clock at f≃31.25 kHz.

FIG. 11 shows h* calculated from equation (25) using K′e as measured by the reference probe vs. mass of microcrystalline cellulose (MCC) introduced into the exemplary prototype cylindrical Capacitance Level Detector of the present invention. The x-axis represents the mass of the MCC (in grams) and the y-axis represents h*.

FIG. 12 shows a photograph of the sensor/guard assembly of the prototype cylindrical Capacitance Level Detector, prior to assembly of the prototype. Shown is the position of the sensor (39), as attached to the inside surface of the hemi-cylindrical guard (40). The sensor is separated from the guard by plastic mesh spacers (41).

FIG. 13 shows the rear view of the sensor/guard assembly of FIG. 12. Depicted is the exposed sensor on the outside surface of the hemi-cylindrical guard.

FIG. 14(A) shows how a strip of plastic insulating material (42) was bonded to the bottom of the outside wall of hemi-cylindrical guard after imbibing the plastic strip with a small amount of adhesive. FIG. 14(B) shows a view of the outside wall of the hemi-cylindrical guard with the plastic insulating strip (42) attached. FIG. 14(c) shows the inside view of the assembly of FIG. 14(b), with the sensor (43) in place on the inside wall of the hemi-cylindrical guard.

FIG. 15 shows the top view of the assembled prototype cylindrical Capacitance Level Detector after inserting the hemi-cylindrical guard (45) into the cylindrical ground tube and affixing the plastic cap (44) over the top of the assembled apparatus.

FIG. 16 illustrates the steps for making the electrical connection of the sensor strip to its sensor voltage. FIG. 16(A) shows a yellow solder wire (46) and brass washer (47) assembly. FIG. 16(B) shows a nylon washer (48) being affixed to the brass washer of FIG. 16(A). FIG. 16(C) shows a top view of the completed assembly of FIG. 16(B), wherein the dual washer combination is shown as 49. FIG. 16(D) shows the assembly of FIG. 16(C) in place in the BNC wall-mounted connector (50), wherein said assembly is attached to the sensor through-hole using a screw (51) placed through the brass and nylon washers of the assembly of FIG. 16(C). The solder wire is denoted as 46.

FIG. 17(A) shows the compression spring (52) in place over the solder wire (46) and washer assembly after said assembly is put in place in the sensor boss, as depicted in FIG. 16(D). FIG. 17(B) shows the assembly depicted in FIG. 17(A), wherein the stainless-steel adaptor (53) is covering the compression spring. 54 denotes the sensor boss, 55 denotes the threaded hole where the coaxial connector (BNC connector) is affixed, and 56 shows the Delrin sleeve before it is put into place on the sensor assembly.

FIG. 18 shows the final assembly of the sensor assembly of the prototype cylindrical Capacitance Level Detector Capacitance with the set screw, Delrin sleeve, guarded adapter and coaxial cable connector in place.

FIGS. 19A-D are schematic perspective, side, longitudinal cross-sectional, and lateral cross-sectional views of one example of feeding tube for use with a reference probe.

FIGS. 20A-D are schematic top, perspective, side and longitudinal cross-sectional views of one example of a sensor for a reference probe.

FIGS. 21A-D are schematic top, perspective, side and longitudinal cross-sectional views of one example of cup for a reference probe.

FIGS. 22A-D are schematic side, top, perspective, and plan views of one example of reference guard for a reference probe.

FIGS. 23-38 are photographs showing the assembly of a reference probe at various stages in the process.

FIGS. 39-41 are schematic perspective views of several examples of tubes having reference probes.

### DETAILED DESCRIPTION OF THE INVENTION

### Definitions and Abbreviations

The terms used herein have their ordinary meaning and the meaning of such terms is independent at each occurrence thereof.

The term “level detector guard,” as used herein, refers to the guard surface of the Capacitance Level Detector of the present invention.

The term “NIR port,” as used herein, refers to the port on the Capacitance Level Detector apparatus used to insert a near-infrared (NIR) instrument. The NIR port illustrates how other instruments can be deployed in the level detector simultaneously without affecting its performance.

The term “reference probe guard,” as used herein, refers to the guard surface of the reference probe that is used with the Capacitance Level Detector of the present invention.

The term “sensor,” as used herein, refers to the sensor surface of a capacitance probe. In the Capacitance Level Detector of the present invention, the term “sensor” refers to either the sensor of the Capacitance Level Detector of the present invention, or to the sensor of the reference probe that is used with the Capacitance Level Detector of the present invention.

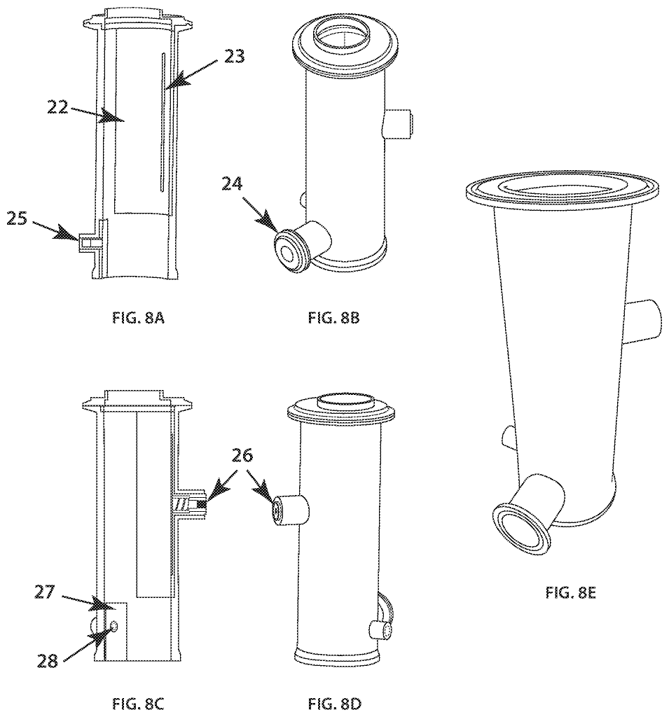

The term “sensor adapter,” as used herein, refers to the adapter piece that connects: (1) the sensor surface of the Capacitance Level Detector to its processing electronics; and (2) the guard of the reference probe to the processing electronics (see FIG. 8(C)).

### The Capacitance Level Detector

The present invention provides a Capacitance Level Detector useful for the continuous and non-invasive measurement of the level and/or mass of a non-conductive or weakly-conductive bulk material in a vessel, while said bulk material is inside the vessel, and wherein the measurement is taken inside the vessel, and wherein the instrument produces level and/or mass as continuous functions of time and amount of said bulk material inside the vessel.

In one embodiment, for the Capacitance Level Detector of the present invention, the vessel acts as the Capacitance Level Detector, and the vessel comprises a sensor, an electrically insulated guard surface surrounding the sensor, and an electrically insulated ground surface.

In another embodiment, for the Capacitance Level Detector of the present invention, the vessel is a cylindrical tube of concave cross-section.

In another embodiment, for the Capacitance Level Detector of the present invention, the vessel is an oval-shaped tube.

In another embodiment, for the Capacitance Level Detector of the present invention, the vessel is a square-shaped tube.

In another embodiment, for the Capacitance Level Detector of the present invention, the electrically insulated guard surface is part of the tube wall.

In still another embodiment, for the Capacitance Level Detector of the present invention, the electrically insulated ground surface is part of the tube wall.

In yet another embodiment, for the Capacitance Level Detector of the present invention, the sensor is attached to the inside surface of the tube wall comprising the electrically insulated guard surface.

In another embodiment, for the Capacitance Level Detector of the present invention, the sensor is a conductor that is attached to the inside surface of the tube.

In a further embodiment, for the Capacitance Level Detector of the present invention, the sensor is connected to processing electronics by one or more inner conductors, wherein the one or more inner conductors reside inside a coaxial cable surrounded by one or more outer conductors held at the guard voltage, and wherein the processing electronics reside outside the vessel.

In one aspect, the present invention provides a method useful for the continuous and non-invasive measurement of the level and/or mass of a non-conductive or weakly-conductive bulk material in a vessel (the “capacitance level measuring method”), wherein the vessel comprises a sensor, an electrically insulated guard surface surrounding the sensor, and an electrically insulated ground surface, and wherein the method comprises the steps of:
a) introducing the non-conductive or weakly-conductive bulk material into the vessel;
b) continuously measuring the voltage between the electrically insulated guard surface while said bulk material is inside the vessel; and
c) correlating the voltage measurements to the level and/or mass of said bulk material, while said bulk material resides in the vessel at the time of said measurements.

The Capacitance Level Measuring Method may be useful, for example in sand casting, and chutes, and in silos in the automotive, chemical, mining, space exploration and pharmaceutical industries.

In one embodiment, for the capacitance level measuring method, the non-conductive or weakly-conductive bulk material is static inside the vessel.

In another embodiment, for the capacitance level measuring method, the non-conductive or weakly-conductive bulk material is flowing through the inside of the vessel.

In another embodiment, for the capacitance level measuring method, the vessel is a tube of concave cross-section.

In still another embodiment, for the capacitance level measuring method, the vessel is a cylindrical tube of concave cross-section.

In another embodiment, for the capacitance level measuring method, the vessel is an oval-shaped tube.

In another embodiment, for the capacitance level measuring method, the vessel is a square-shaped tube.

In yet another embodiment, for the capacitance level measuring method, the electrically insulated guard surface is part of the tube wall.

In another embodiment, for the capacitance level measuring method, the electrically insulated ground surface is part of the tube wall.

In another embodiment, for the capacitance level measuring method, the sensor is attached to the inside surface of the tube wall comprising the electrically insulated guard surface.

In a further embodiment, for the capacitance level measuring method, the sensor is a conductor that is attached to the inside surface of the tube.

In another embodiment, for the capacitance level measuring method, the sensor is connected to processing electronics by one or more inner conductors, wherein the one or more inner conductors reside inside a coaxial cable surrounded by one or more outer conductors held at the guard voltage, and wherein the processing electronics reside outside the vessel.

In another embodiment, for the capacitance level measuring method, the non-conductive or weakly-conductive bulk material is a powder.

In yet embodiment, for the capacitance level measuring method, the non-conductive or weakly-conductive bulk material is a powder, wherein said powder comprises a drug substance.

In a further embodiment, for the capacitance level measuring method, the non-conductive or weakly-conductive bulk material is a dielectric fluid.

It is to be understood that the embodiments provided above are understood to include all embodiments, including embodiments as resulting from combinations of the above embodiments.

### Non-Conductive and Weakly Conductive Materials for Measurement

The Capacitance Level Detector is useful for the continuous and non-invasive measurement of the level and/or mass of a non-conductive or weakly-conductive bulk material in a vessel.

Non-limiting examples of non-conductive and weakly-conductive bulk materials that can be measured using the present methods include, but are not limited to, the following: bulk solids including food powders, pastes, dried foods and flakes, pharmaceutical powders, sand, cement, powdered detergents, agricultural grains such as corn or wheat, dust, and dry refuse. Example of weakly conductive powders and grains include, but are not limited to, all of the above, if they contain small amounts of moisture and/or solvent purposefully or by accident, and natural powders and grains such as snow, arid soils, volcanic material, and planetary regolith. Dielectric liquids include lubricants, fuels, beauty products, sun protection creams, and asphalt.

In one embodiment, the non-conductive or weakly-conductive bulk material is a powder.

In another embodiment, the non-conductive or weakly-conductive bulk material is a powder, wherein the powder comprises a drug substance.

In one embodiment, the non-conductive or weakly-conductive bulk material is a fluid.

In another embodiment, the non-conductive or weakly-conductive bulk material is a dielectric fluid.

### Principle

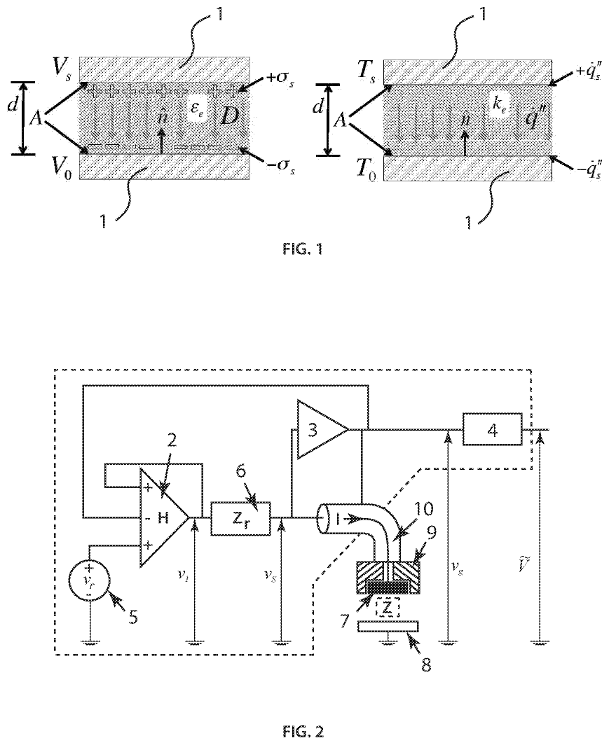

Two adjacent conductors separated by a dielectric medium and held at different voltages, such as those described in FIG. 1(a), accumulate surface charges of opposite signs with density σₛ and magnitude proportional to the voltage difference (Vₛ−V₀). The proportionality constant between overall charge and (Vₛ−V₀) is the capacitance C. If the two conductors are semi-infinite planes of surface area A with distance d, the total accumulated charge magnitude on either one is Qₛ=σₛA=C(Vₛ−V₀).

The voltage difference drives a reverse gradient E=−∇V, referred to as the electric field. If the intervening medium has an effective dielectric permittivity ϵₑ, the constitutive behavior of the medium relates the displacement field D to the electric field, D=ϵₑE. Meanwhile, if charges do not accumulate within the medium itself, Gauss' law yields ∇·D=0. This equation is subject to surface boundary conditions of the form D=σₛ\hat{n}. For the simple system of two semi-infinite parallel plates, such as described by the left side diagram of FIG. 1, combining these equations yields C=ϵₑA/d.

To understand the physics, it is more intuitive to consider the equivalent steady conduction heat transfer, as described by FIG. 1(b). As an alternative to ∇·(ϵₑ∇V)=0, such analogy is also convenient to simulate the behavior of a capacitance probe with complicated geometry and/or an inhomogeneous dielectric medium using readily available software that solves the elliptic Laplace equation ∇·(kₑ∇T)=0 for conduction heat transfer.

In general, a probe separated by a medium of constant Ee without charge accumulation has a capacitance described by equation 1:

C=ϵₑ [symbol] , (1)

where [symbol] is its characteristic length. In the parallel plate example of FIG. 1, [symbol] =A/d. Meanwhile, the effective dielectric constant, typically expressed in fF/mm (10⁻¹⁵ F/10⁻³ m), possess both a real and an imaginary part, described by equation 2:

ϵₑ=ϵ′ₑ−iϵ″ₑ (2)

where i²=−1. In this case, a general medium acts as a resistance in parallel with a capacitance; the real part δ′ₑ corresponds to capacitance, and the imaginary part ϵ″ₑ to conductance. Nearly pure dielectric media, such as glass, plastic or dry powders, have ϵ″ₑ≃0. However, weakly conductive media, such as snow, moist sand, or humid pharmaceutical powders, can exhibit a significant imaginary part. When the intervening medium is a gas, such as dry or moist air, it possesses a dielectric constant nearly equal to that in vacuo: (ϵ₀=8.854 fF/mm). If not, it is useful to introduce a dimensionless ratio Kₑ called the effective dielectric constant. Like ϵₑ, Kₑ possesses both real and imaginary parts, as described by equation 3:

Kₑ≡ϵₑ/ϵ₀=K′ₑ−iK″ₑ (3)

For air, ϵₑ≃ϵ₀, so Kₑ≃K′ₑ and K″ₑ=0.

Implementation of this technique is inspired by work on non-invasive, instantaneous measurements of bulk density in fluidized beds, density and velocity in snow avalanches, compaction and dielectric signature of snow packs, and solid volume fraction and moisture content in desert sands. Applications to pharmaceutical powders can be based on a similar principle.

FIG. 2 shows a generic sketch of commercially-available processing electronics. In this design, a generic sensor with impedance Z to ground receives an alternating current i with amplitude maintained constant by stabilizing the ac voltage (υₛ−υ₁) around the reference impedance Zᵣ≡m−in. This feedback control uses an op amp of high gain H>>1 fed with a sinusoidal voltage yr. A buffer amplifier of unit gain but high input impedance samples the resulting voltage υs without drawing a significant current. By keeping guard and sensor voltages equal, stray and cable capacitance are eliminated, and the electric field emanating from the sensor is precisely confined. Such electronics produces a rectified voltage \tilde{V} directly proportional to the modulus of Z. Therefore, if Z is purely capacitive, \tilde{V} is inversely proportional to capacitance. If not, the phase between oscillator and guard can be used to extract both the real and imaginary parts of Z from Eqs. (7)-(10) or, equivalently, its capacitive and conductive components. All components within the dashed line, except the oscillator, are called the “preamp”. A typical system includes a single clock feeding several preamps operating at a single frequency on the order of tens of kHz.

As shown in FIG. 2, probes record the impedance of the medium between a sensor and a ‘target’ (ground) conductor held at a constant zero reference voltage. To achieve this, conductors carrying a sensor voltage are surrounded by a ‘guard’ driven at precisely the same potential by an independent circuit. By guiding electric field lines that penetrate a powder at the probe face, the guard focuses the extent of the probe's measurement volume originating from the sensor, thereby avoiding external interference known as ‘stray’ capacitance. Because the guard is also connected to the outer conductor of a high-quality coaxial cable connecting probe and processing electronics, it also shields the wire and all electrical components carrying the sensor voltage. Therefore, because there can be no charge accumulation in the cable, the latter's capacitance does not perturb the measurement, unlike conventional bridge circuits.

This technique allows precise detection of extremely small capacitances as low as Cₐᵢᵣ˜10 fF when the probe is exposed to air. It works best when the sensor capacitance is on that order. However, by boosting the voltage amplitude of the oscillator, one can handle greater capacitances up to ˜1 nF. Therefore, equations (1)-(3) above suggest that typical probe sensors have millimetric to decimetric dimensions with this technique.

As described in Louge, et al., Cold Regions Science and Technology (1997), 25:47-63, the circuit of FIG. 2 achieves two objectives. First, by keeping constant the amplitude of the ac voltage across the reference impedance Zᵣ≡m−in, an AC current of constant amplitude is supplied to the sensor surface. Second, by sampling the resulting sensor voltage with a ‘buffer’ op amp of very large input impedance, the circuit produces a robust guard voltage that follows the sensor's without drawing any significant current from the latter. The feedback control maintaining the ac voltage υₛ−υ₁ across Zᵣ is an op amp of high gain H>>1 fed by a highly stable sinusoidal oscillator of frequency f called the ‘clock.’ The circuit therefore produces a guard voltage υ_{g} of the same frequency, and with amplitude υ_{g} proportional to the magnitude of the impedance being measured, as described by equation 4:

$$Z = \frac{1}{2 π fi {ϵ}_{0} ℓ {K}_{e}} . \qquad ( 4 )$$

Finally, a rectifier similar to that used in AM radio outputs a dc voltage, denoted by a tilde, that is proportional to guard amplitude. Therefore, the ratio x of the guard voltage V_{g,air} in air and its counterpart υ_{g} in the presence of the dielectric medium of interest or, equivalently, the ratio of the corresponding rectified voltages, yield the magnitude of the medium's effective dielectric constant, as described by equation 5:

$$χ ≡ \frac{{V}_{g , air}}{{V}_{g}} = \frac{{\tilde{V}}_{air}}{\tilde{V}} = \vert \frac{{Z}_{air}}{Z} \vert = \vert {K}_{e} \vert = \sqrt{{K}_{e}^{′2} + {K}_{e}^{″2}} . \qquad ( 5 )$$

As described elsewhere herein, establishing this ratio is generally sufficient to record powder level and/or mass holdup. However, as in snow or moist sand, the technique can also yield the ratio K″ₑ/K′ₑ, which is correlated with the amount of moisture held by particles, adsorbed in the case of sand, or absorbed in pharmaceutical powders. To that end, one records the phase by which the guard leads the clock, as described by equation 6:

$$tan ϕ = \frac{tan φ - m / n}{1 + ( m / n ) tan φ + 1 / [ 2 π fn ( 1 - H ) {ϵ}_{0} ℓ {K}_{e}^{′} ]} . \qquad ( 6 )$$

By analogy to radio and radar signal attenuation, K″ₑ/K′ₑ=tan φ is called the ‘loss tangent’. Two quantities naturally arise in the phase equation (6). The first is the ‘amplifier tangent’ (tan ϕₛ), as described by equation 7:

$$tan {ϕ}_{s} ≡ - \frac{m}{n} \qquad ( 7 )$$

which is an attribute of a given preamp channel. The second, which we call the ‘correction tangent’ (tan ϕₚ), combines the response of a preamp to a specific sensor capacitance in air, as described by equation 8:

tan ϕₚ≡−1/[2πfn(1−H)ϵ₀ [symbol] ]. (8)

Combining Eqs. (5)-(8), one extracts the real and imaginary parts of the medium within the probe measurement volume, as described by equations 9 and 10:

K′ₑ=|cos(ϕ−ϕₛ)[χ²−cos²ϕₛ sin²ϕ tan²ϕₚ]^{1/2}+cos ϕₛ sin ϕ sin(ϕ−ϕₛ)tan ϕₚ (9)

And

K″ₑ=[χ²−K′ₑ²]^{1/2} (10)

Note that, if tan ϕₚ —>0, then equation (6) simplifies to tan ϕₐᵢᵣ≡−m/n=tan ϕₛ, where ϕₐᵢᵣ is the phase with only air present, and therefore the loss tangent is simply tan(ϕ−ϕₐᵢᵣ)=K′ₑ/K′ₑ≡tan φ. In other situations when tan ϕₚ is finite, then Eqs. (9)-(10) must be used to find K″ₑ/K′ₑ and ultimately relate this ratio to adsorbed moisture through calibrations of the powder.

In short, by measuring

$$χ ≡ \frac{{V}_{g , air}}{{V}_{g}} and ϕ ,$$

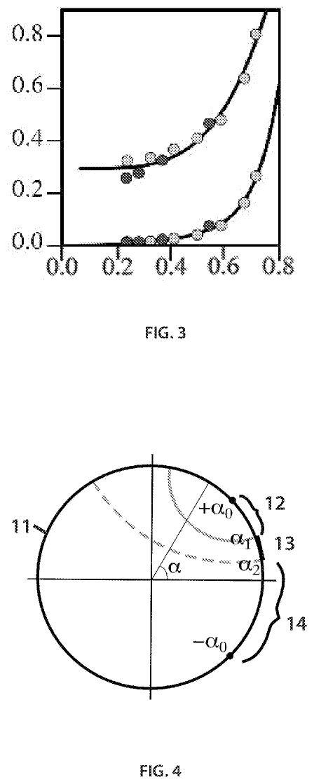

the processing electronics yields the modulus |Kₑ|=\sqrt{K′ₑ²+K″ₑ²} and the loss tangent tan φ=K″ₑ/K′ₑ or, equivalently, the real and imaginary parts of the dielectric constant K′ₑ and K″ₑ. Because loosely-packed pharmaceutical powders can possess values of K′ₑ just above one and/or K″ₑ just above zero, it is important to determine V_{g,air}, V_{g} and ϕ with great accuracy, and this determination is described in the Examples section below and illustrated in FIG. 3, which graphically illustrates measurements of K′ₑ and K″ₑ using microcrystalline cellulose as the media.

### Electric Field

It is necessary to provide a general expression for the electrostatic field in a tube slice of circular cross-section with sensor, guard and ground sectors of the conductive wall. From this general analysis, we will derive expressions for capacitance and extent of the measurement volume for two generic probes. The first probe consists of a vertical sensor strip designed to shed field lines across the grounded opposite wall of the tube, thereby producing a signal sensitive to powder level and/or mass holdup in the tube, as described below in the section “Level Sensor.”

The second probe has a sensor disk conformal with the tube inner wall, as described below in the section labeled “Reference Measurement.” When it is fully immersed in powder near the bottom of the Capacitance Level Detector, its purpose is to provide a reference that obviates the need for an independent calibration of the powder's dielectric constant for level measurements, or that allows an instantaneous determination of mass holdup.

Consider a semi-infinite probe on a circular cylinder of radius R and height H, as described, for example, in FIG. 4. The sensor occupies the angular sector of the wall α₂<α<α₁; it is surrounded by guard within −α₀<α<α₂ and α₁<α<+α₀, where α₀>0 and −α₀<α₂<α₁<+α₀. The complex potential for a planar capacitance geometry with singularities at x=±α is described by equation 11:

ϕ=(V_{g}/π)i ln[( [symbol] +a)/( [symbol] −a)] (11)

where V_{g} is the guard (or sensor) voltage. We then exploit the conformal mapping, as described by equation 12:

$$= a ( \frac{sin {α}_{0}}{1 + cos {α}_{0}} ) i ( \frac{+ R}{- R} ) \qquad ( 12 )$$

to transform the real axis of the original complex plane to a circle of radius R in the mapped plane z=x+iy, thereby bringing singularities to the azimuth angles α=±α₀. The complex potential in the mapped plane is described by equation 13:

$$Φ ≡ V + iε = i {V}_{g} ln [ \frac{- R + i c ( R + )}{R - + ic ( R + )} ] \qquad ( 13 )$$

where

$$c = \frac{sin {α}_{0}}{( 1 + cos {α}_{0} )} ,$$

and [symbol] and ε are the local voltage and field functions, respectively.

In general, the capacitance Γ per unit cylinder height along a line from point 1 to point 2 on the cylinder wall that does not include a singularity is described by equation 14:

Γ=ϵₑ/(πV_{g})ℑ(Φ₁−Φ₂) (14)

where ℑ=denotes the imaginary part. For the circular arc joining the two ends of the sensor sector at [symbol] ₁=Re^{iα}^{₁} and [symbol] ₂=Re^{iα}^{₂}, we find the capacitance per unit height, as described by equations 15 and 16:

Γ=ϵₑF(α₀,α₁,α₂) (15)

where

$$F ( {α}_{0} , {α}_{1} , {α}_{2} ) ≡ \frac{1}{2 π} ln [ \frac{1 - cos ( {α}_{0} + {α}_{1} )}{1 - cos ( {α}_{0} - {α}_{1} )} \times \frac{1 - cos ( {α}_{0} - {α}_{2} )}{1 - cos ( {α}_{0} + {α}_{2} )} ] \qquad ( 16 )$$

wherein FIG. 4 illustrates the results for arbitrary values of α₀, α₁, and α₂.

We exploit the result of equation 16 in the design of the Capacitance Level Detector of the present inventions that sheds electric field lines from a thin vertical sensor of height H and angular sector δ (α₂=−δ/2<α<+δ/2=α₁) to a ground that cover the opposite half tube

$$( π / 2 < α < 3 π / 2 , i . e . {a}_{0} = \frac{π}{2} rad ) ,$$

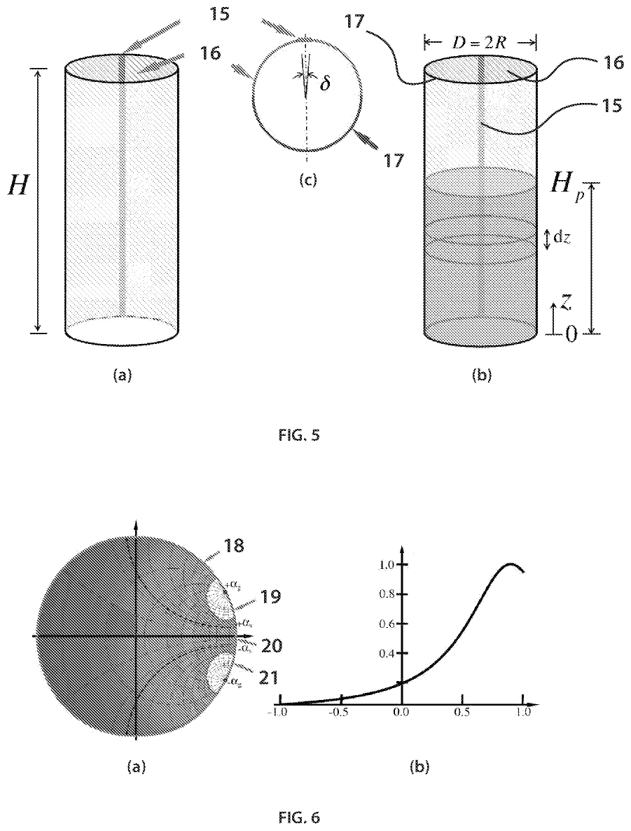

as described by FIG. 5. When δ is small, the function in equation (16) becomes, to leading order:

F(α₀,α₁,α₂)≃δ/π (17)

so the capacitance per unit height is ϵₑΛ, where:

Λ≃2W/(πD) (18)

is dimensionless, and W and D are, respectively, the sensor width and tube diameter.

When the Capacitance Level Detector is partially covered by a powder along its height, the dielectric constant is not uniform along the vertical direction of the probe measurement volume, as shown in FIG. 5(b). However, by symmetry, the electric field remains horizontal despite the discontinuity in Kₑ at the free surface. Therefore, contributions of each slice of thickness dz constitute parallel impedances between sensor and ground with elementary length scale d [symbol] =Λdz. Because the instrument is sensitive to the inverse of the overall impedance Z (equation 5), it naturally records the arithmetic average K̅ₑ in the tube.

In general, if Kₑ is expected to vary within the measurement volume of a capacitance probe, the latter should be designed to shed an electric field from the sensor that is perpendicular to the gradient of Kₑ, as described by equation 19:

E·∇Kₑ=0 (19)

so elementary contributions to the overall sensor capacitance are parallel and add up linearly.

Combining this condition with Gauss' law D=ϵ₀E·∇Kₑ+ϵ₀Kₑ∇·E=0 also implies a divergence-free electric field ∇E=0 that remains independent of Kₑ. In this case, the recorded voltage ratio χ̅ is a meaningful measure of the volume-average dielectric constant K̅ₑ as the underlying field does not change when powder is introduced. Such is the case for this Capacitance Level Detector with horizontal electric field, since a stratification gradient of the powder, if significant, should be aligned with the vertical. Using Eqs. (4) and (18), one arrives at equation 20:

$$\frac{1}{Z} = 2 π fi {∈}_{0} Λ {\int }_{𝓏 = 0}^{{H}_{P}} {K}_{e} d 𝓏 = 2 π fi {∈}_{0} Λ [ ( H - {H}_{P} ) + {\int }_{𝓏 = 0}^{{H}_{P}} ( {K}_{e}^{′} - {iK}_{e}^{″} ) dz ] \qquad ( 20 )$$

where the first term in brackets arises from the air gap of height (H−Hₚ), and the second integrates possible stratification of Kₑ that may arise from an inhomogeneous bulk density in the powder column. Then, the impedance ratio is related to the relative filling h*≡Hₚ/H as:

$$\frac{{Z}_{air}}{Z} = 1 + {h}^{*} ( {\overline{K}}_{e}^{′} - 1 ) - i {h}^{*} {\overline{K}}_{e}^{″} \qquad ( 21 )$$

where the overbar denotes volume-averaging within 0<z<H. As long as K̅ₑ is known, h* is derived as described in equation 22, from the recorded voltage ratio χ̅ using equation (5),

χ̅=V_{g,air}/V_{g}=\sqrt{[1+h*(K̅′ₑ−1)]²h*²K̅″ₑ²} (22)

while the overall loss tangent yields

tan φ̅=h*K̅″ₑ/[1+h*(K̅′ₑ−1)]. (23)

Solving equation (22) yields:

h*=[\sqrt{χ̅²∇_{K}²−K̅″ₑ²}−(K̅′ₑ−1)]/∇_{K}² (24)

where ∇_{K}²≡(K̅′ₑ−1)²+K̅″ₑ².

If the powder has no significant imaginary part (K″ₑ≃0), then equation 24 simplifies to

$${h}^{*} = \frac{( \overline{C} / {C}_{air} ) - 1}{{\overline{K}}_{e}^{′} - 1} = \frac{\overline{χ} - 1}{{\overline{K}}_{e}^{′} - 1} . \qquad ( 25 )$$

Therefore, quantitative level measurements require prior knowledge of the rectified voltage \tilde{V}ₐᵢᵣ in air, and a calibration yielding Kₑ. If the powder is strongly stratified, then such calibration must be achieved in situ by recording χ̅ with the tube entirely filled with powder (h*=1→χ̅²=K̅′ₑ²+K̅″ₑ² and tan φ̅=K̅″ₑ/K̅′ₑ).

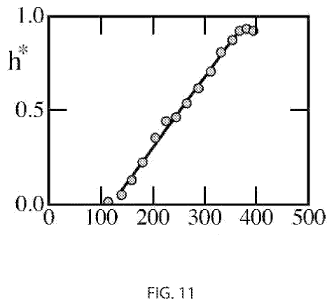

If instead Kₑ is uniform in the tube, but is expected to change with time, it can be found using the reference probe that we describe next. FIG. 11 graphically shows the results of a test of this concept, obtained by pouring known masses of microcrystalline cellulose into the Capacitance Level Detector prototype.

### Reference Measurement

In pharmaceutical operations it is possible for Kₑ to evolve, for instance if the powder changes composition or absorbs moisture. If variations of Kₑ are sufficiently large, it may be essential to monitor it continuously with a reference probe. This can be achieved by deploying a small cylindrical sensor with axis perpendicular to the wall near the bottom of the Capacitance Level Detector that powder covers permanently. The sensor is inserted through a guard covering a cylindrical sector of the wall −α_{g}<α<+α_{g}. To avoid distortion of the two-dimensional field emanating from the sensor, such guard should extend vertically about one Capacitance Level Detector cylinder radius R above and below the sensor.

Alternatively, this precaution can be avoided if the processing electronics has the “multiplxing” capability to connect two separate probes to the same preamplifier. In this case, because the processing electronics can interrogate each probe separately while keeping the other at the common guard voltage, the Capacitance Level Detector and reference probe can share a common guard, and therefore be placed closer to each other without interference. Such multiplexing can be used if dielectric properties of the material in the vessel change relatively slowly, so that it is not necessary to interrogate the reference probe frequently.

In the reference probe configuration, the sensor of radius Rₛ sheds field lines across the tube, as illustrated in FIG. 6(a). Each elementary slice of the sensor surface at elevation z from its axis has a different azimuth interval −αₛ<α<+αₛ contributing the elementary capacitance length d [symbol] =F(α_{g}, αₛ, −αₛ)dz, where f is the function in equation (16)

$${a}_{s} ≡ arc sin [ ( \frac{{R}_{s}}{R} ) \sqrt{1 - {u}^{2}} ] , and u ≡ 𝓏 / {R}_{s} .$$

The capacitance length, defined in equation (1), is found by numerical integration, as described by equation 26:

[symbol]

=2Rₛ∫ᵤ₌₀¹F(α_{g},αₛ,−αₛ)du. (26)

In this non-invasive design, the angular sector of the guard governs a trade-off between detectable capacitance magnitude and extent of the measurement volume. Because powders do not necessarily flow freely, and occasionally accumulate near walls, it is important that the reference probe be sensitive to as wide a cross-section of the tube as possible. In this context, it would be tempting to adopt a configuration similar to the level sensor illustrated in FIG. 5, where the measurement volume traverses the entire tube. However, such guard sector with α_{g}=α₀=π/2 could produce a capacitance too small to detect. Therefore, one should decrease α_{g} without compromising the instrument's reach into the tube. A measure of this reach is the farthest distance B between the Capacitance Level Detector wall and the outermost field line shed from the sensor, as shown in FIG. 6(a). To calculate B, we note that the imaginary part of Φ in equation (13) is constant on field lines. Therefore, the line shed from a point on the tube with 0<α<α_{g} is a circle of center [x_{c}; y_{c}]=R[cos α_{g}; (1−cos α cos α_{g})/sin α] and radius R_{f}=R (cos α−cos α_{g})/sin α, and its farthest distance from the wall can be calculated using equation 27:

B=R−\sqrt{x_{c}²+y_{c}²}+R_{f} (27)

where x_{c}, y_{c} and R_{f} are evaluated at the largest sensor azimuth αₛ.

A convenient measure of the influence of a material point on the recorded capacitance is the magnitude of the local electric field E=∥∇V∥=∥dΦ/dz∥=|∂ [symbol] /∂x−i∂ [symbol] /∂_{y}∥. As the progressively darker shading in FIG. 6(a) and its corresponding graph (FIG. 6(b)) indicate, the field decays progressively away from the sensor, but retains significant strength in the region bound by two dashed field lines and extending approximately a quarter of the pipe diameter from the sensor. In that measurement volume, the field remains nearly unidirectional perpendicular to the tube wall. Therefore, if the powder is stratified vertically or in the azimuthal direction, equation (19) is upheld, and this probe should record a proper arithmetic average value for Kₑ.

An alternative to a circular sensor of the reference probe is to make the sensor into a curved rectangular strip of height hₛ spanning −αₛ<α<αₛ. This can be achieved, for example, by creating a curved printed circuit board (PCB) lining the inner surface of the vessel. In this case, the reference probe has a capacitance length hₛF(α_{g}, αₛ, −αₛ), where the function F is given by Eq. (16).

### Mass Holdup Measurement

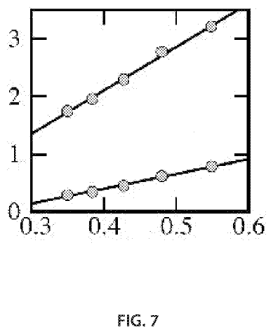

The dielectric constant of powder suspensions rises with their bulk density ρ. With pharmaceutical powders at or above loose packing, the relation is nearly linear near a reference bulk density ρ₀, and it can be established using a capacitance instrument that progressively compresses them at known moisture content, similar to the instrument described in Louge, et al., Cold Regions Science and Technology (1997), 25:47-63 (see FIG. 7), as described by the dual equation 28:

$${K}_{e}^{′} ≃ {K}_{{e}_{0}}^{′} + \frac{\partial {K}_{e}^{′}}{\partial ρ} {\vert}_{0} ( ρ - {ρ}_{0} ) \qquad ( 28 )$$

$${K}_{e}^{″} ≃ {K}_{{e}_{0}}^{″} + \frac{\partial {K}_{e}^{″}}{\partial ρ} {\vert}_{0} ( ρ - {ρ}_{0} ) .$$

Because the Capacitance Level Detector upholds criterion (19), its inverse impedance is also linear in K̅′ₑ and K̅″ₑ (equation 21), and equation (22) can be combined with equation (28) to yield the mass holdup M=AHρ̅ within the height 0<z<H of the level sensor of cross-section A, as described by equation 29:

$$\frac{M}{A H} = {ρ}_{0} + \frac{{\overline{χ}}^{2} - {χ}_{0}^{2}}{2 {h}^{*} \{ [ 1 + {h}^{*} ( {K}_{{e}_{0}}^{′} - 1 ) ] \frac{\partial {K}_{e}^{′}}{\partial ρ} {\vert}_{0} + {h}^{*} {K}_{{e}_{0}}^{″} \frac{\partial {K}_{e}^{″}}{\partial ρ} {\vert}_{0} \}} \qquad ( 29 )$$

where χ₀ is the voltage ratio recorded in a full Capacitance Level Detector at the bulk density ρ₀. The Prototype Cylindrical Capacitance Level Detector

FIG. 8 provides perspective views of the prototype cylindrical Capacitance Level Detector and reference probe. In this design, the prototype cylindrical Capacitance Level Detector has a total height of 28 cm and an inner diameter of D≃73 mm. The prototype cylindrical Capacitance Level Detector features a guard 20 cm tall, a sensor strip of height H≃15 cm and width W≃3 mm, conferring it a capacitance of 34 fF in air. The reference probe in FIG. 6 has a guard extending +25 mm above the sensor axis and −38 mm below, and a capacitance of 12 fF in air. The prototype cylindrical Capacitance Level Detector and probes are made of 316 stainless steel. Food-grade epoxy (MASTERBOND™ EP42HT-2FG) binds and insulates sensors and guards.

To avoid stressing the processing electronics, spacings in each probe are set to maintain the capacitance between sensor and ground <800 pF and their mutual resistance >5 MΩ. In addition, the capacitance between sensor and guard is kept <200 pF, including the high quality coaxial cable that connects the probe to the processing electronics. Cable length must produce a resistance <100Ω in its central sensor wire and <2Ω in its outer braided guard. Accordingly, for each probe, adapters are designed to bring sensor and guard voltages to the inner wall surface without short-circuit, while maintaining uninterrupted contact with the processing electronics despite vibrations. Finally, both reference probe and prototype cylindrical Capacitance Level Detector are driven by the same clock but with two different pre-amps (as described in FIG. 2), and they are placed judiciously to minimize mutual interference. (As indicated earlier, an alternative is to drive the Capacitance Level Detector and reference probe with the same multiplexed pre-amp, which interrogates them in sequence).

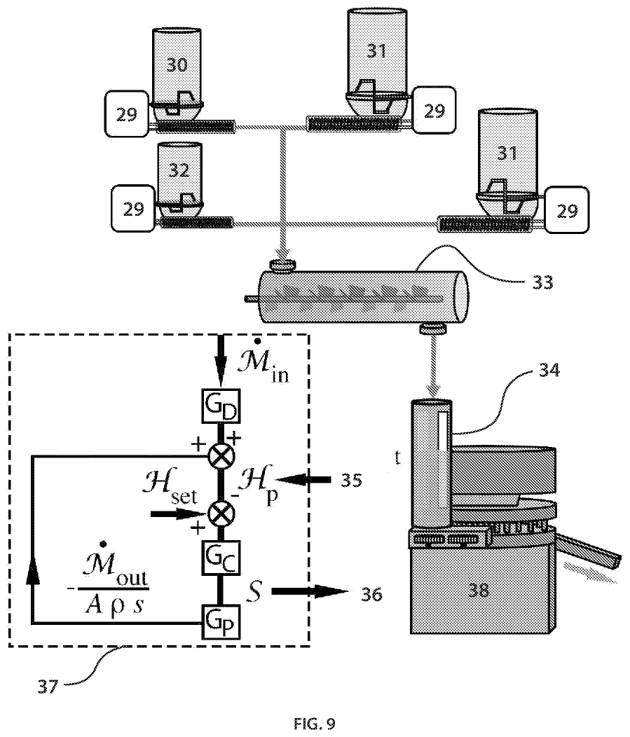

FIG. 9 is a sketch describing a continuous direct compression process where different ingredients of a drug product formulation (active pharmaceutical ingredients, excipients, and lubricants) are fed either individually or in a pre-blended form to a continuous blender. The blended powder then flows through a Capacitance Level Detector into a tablet press where is it compressed to a pre-defined tablet form. To ensure uninterrupted operation and consistent product quality, it is desirable to maintain the powder level around a set point, which is achieved by controlling the tablet press speed based on signals from the Capacitance Level Detector. The feedback control of the powder level is greatly facilitated by continuity in space and time of the Capacitance Level Detector signal. At steady-state, denoted by an overbar, the input mass flow rate \dot{m}ᵢₙ from the blender balances the tablet output mass flow rate \dot{m}ₒᵤₜ. Away from this equilibrium, the mass balance equation at constant bulk density ρ can be calculated using equation 30:

AρdHₚ/dt=\dot{m}ᵢₙ−\dot{m}ₒᵤₜ (30)

where the output mass flow rate is related to the number nₚ of punches making tablets of mass m in the press operating at a rotation speed S, as described by equation 31:

\dot{m}ₒᵤₜ=mnₚS. (31)

Subtracting the steady values from equation (30) and rearranging yields a relation between the Laplace transforms of excursions in speed S, height [symbol] p, and feeder mass flow rate \dot{M}ᵢₙ, as described by equation 32:

[symbol]

p=G_{D}\dot{M}ᵢₙ+G_{P} [symbol] (32)

where G_{D}=(Aρs)⁻¹ and G_{P}=−mnₚ/(Aρs) are load and process transfer functions, respectively, s≡i2□ f_{c} is the Laplace variable, and f_{c} is control frequency. In the dashed rectangle of FIG. 9, [symbol] p/ [symbol] set=G_{C}G_{P}/(1+G_{C}G_{P}) is the transfer function for controlling the powder height set point at a steady input mass flow rate (\dot{M}in=0), where G_{C} is a control transfer function tuned as described in Chen and Seborg, Industrial and Engineering Chemistry Research 41:4807-4822 (2002), and Skogestad, Journal of Process Control 13:291-309 (2003). Similarly, at [symbol] set=0, [symbol] p/\dot{M}in=G_{D}/(1+G_{C}G_{P}) is the closed loop response to variations in load.

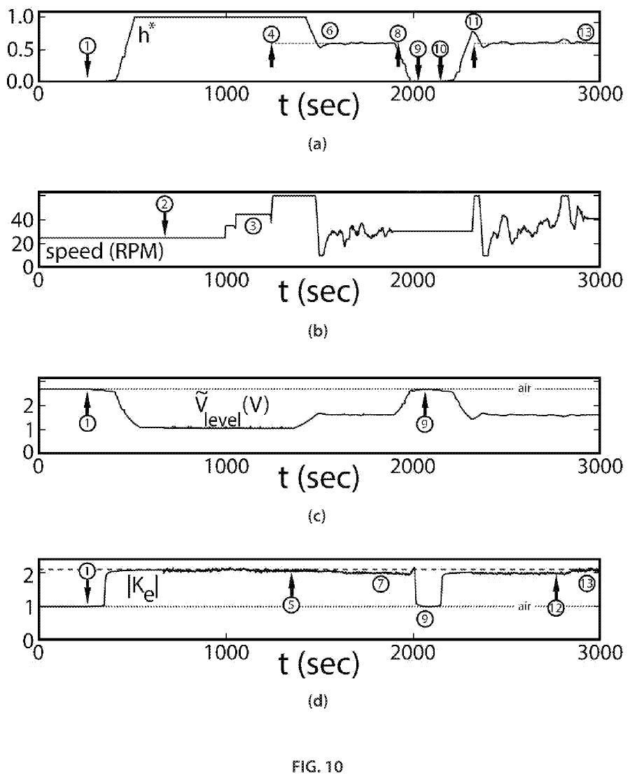

FIG. 10 shows a typical control sequence, with notable events being numbered and described in the Brief Description of the Figures above herein. For simplicity, because Kₑ≃K′ₑ≃|Kₑ| did not vary much in these experiments, we used the value K′ₑ≃2.1 recorded by the reference probe as the press was started (dashed line in the |Ke| time-history) in equation (25). However, we showed that the reference probe could also detect changes in the blend (as denoted using the number “5” in FIG. 10), and therefore would allow adaptive control if Kₑ evolved more significantly. We also noted that the onset of powder flow was accompanied by small excursions in Kₑ, which revealed local density variations, but were inconsequential in the control strategy.

### Examples

### Assembly of Prototype Capacitance Level Detector

A prototype cylindrical Capacitance Level Detector was constructed using the following parts:

1. Cylindrical feed tube (to be kept at ground voltage)

2. Hemi-cylindrical tube (to be kept at guard voltage)

3. Level Sensor strip (to be kept at sensor voltage)

4. Level Detector Adaptor

5. Delrin Sleeve

6. BNC connector

7. Multiple stand 24AWG electrical wire

8. Compression Spring

To join the parts of the prototype, a two-component epoxy, EP42HT-2FG (MasterBond Inc., Hackensack, N.J.) was used as the bonding agent. The two components of the epoxy are provided in separate syringes and mixed immediately prior to use. The dielectric constant of this epoxy is estimated to be between 3.5 and 4.0, at 60 Hz, at room temperature. The density of one component of the epoxy (“Part A”) is approximately 1.22 grams per cc and the density of the other component of the epoxy (“Part B”) is about 0.99 grams per cc. It was most convenient to extrude the two parts from their respective syringe based on volume showed on the syringes. To that end, with a mass ratio A/B=100/30, the corresponding volume ratio A/B=27/10, or 73%-part A by volume and 27%-part B by volume.

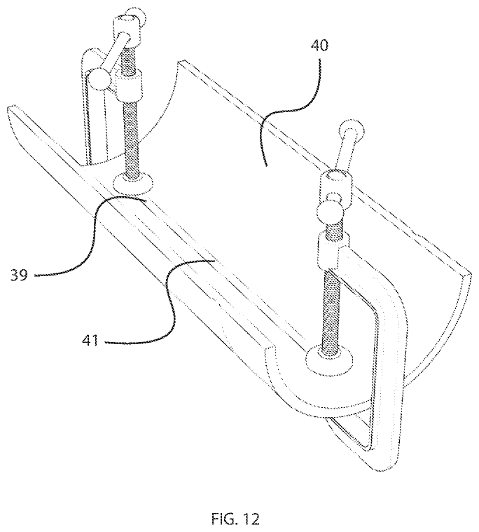

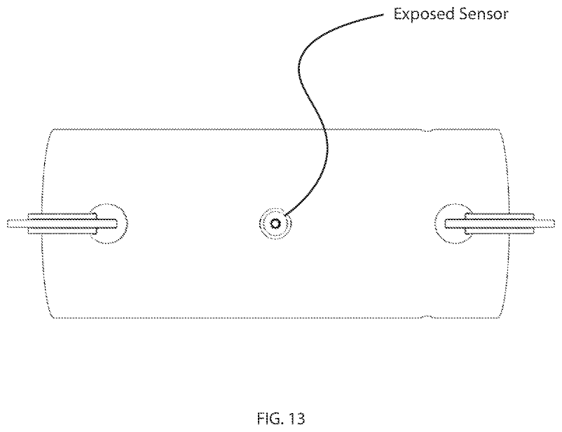

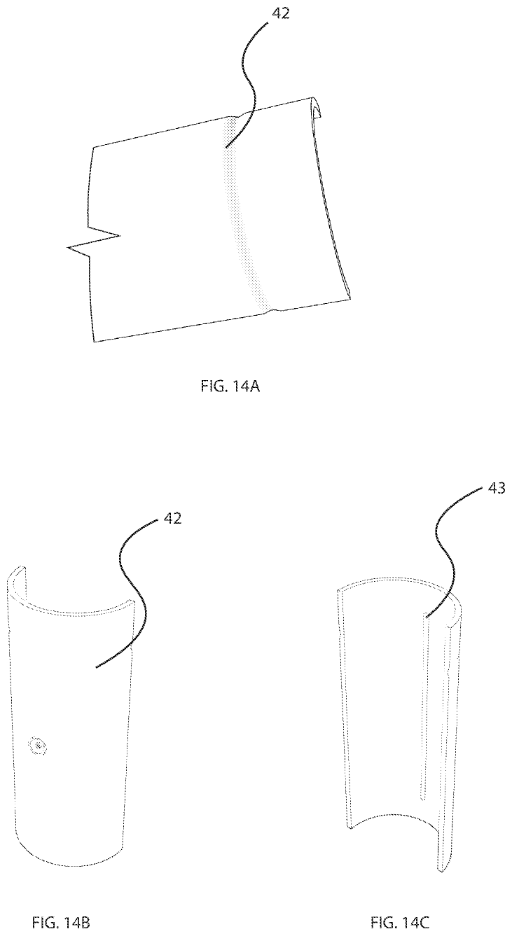

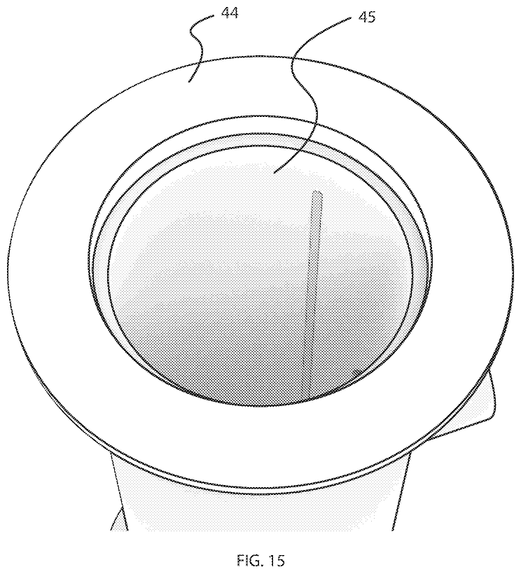

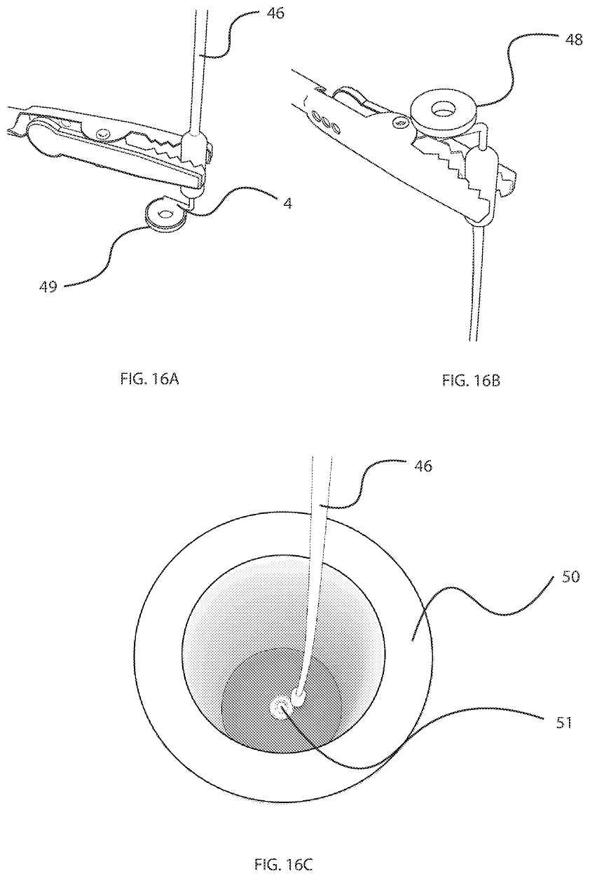

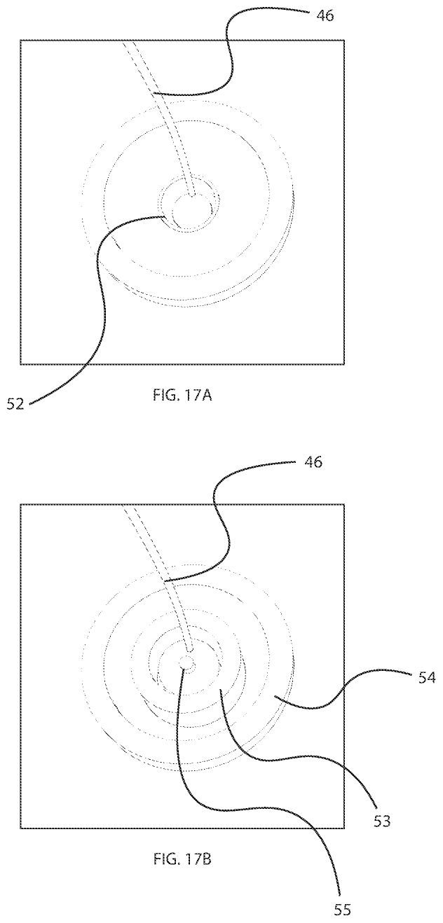

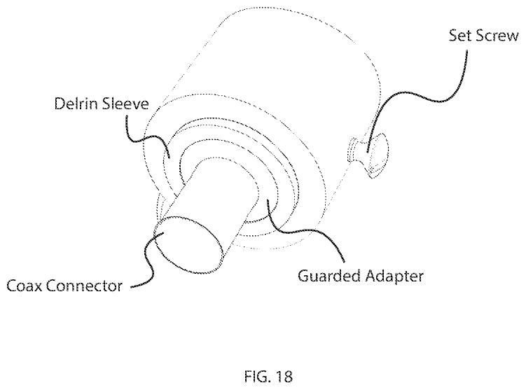

The prototype cylindrical Capacitance-Level Detector was assembled using the following step-by-step procedure:
1. Eight small cuts of polypropylene plastic mesh of 0:021″ thickness were tucked into a slot on the inside surface of the hemicylindrical guard before inserting the sensor (FIG. 12). After the mesh was in place, the sensor was pushed into place. Two C-clamps were used to hold the sensor in place, as depicted in FIG. 12. Small cardboard pieces were inserted between the clamp and the metal parts that the clamp was in contact with, in order to insulate them electrically. A Fluke multimeter verified that the resistance between guard and sensor was effectively infinite.
2. A small amount of EP42HT-2FG MasterBond epoxy was prepared and applied in the gap between sensor and guard, except behind the connector piece, to avoid leaking epoxy that could hamper future guard or sensor connections. The clamped sensor-guard assembly was kept horizontal as shown in FIGS. 12-13 using weight boats and masking tape. The bonded assembly was placed in an oven set to 80° C. and left overnight in order to cure the epoxy.
3. To provide an insulation between the hemi-cylindrical guard and the grounded cylindrical tube into which the hemi-cylindrical guard is to be placed, pieces of plastic semi-circular shim and chemical-resistant polypropylene plastic mesh were carefully measured, cut and glued to the guard surfaces using a very small amount of instant bond adhesive (store-bought “super glue”) as shown in FIG. 14. All shim pieces were cut to have a thickness smaller than the corresponding clearances.
4. The guard-sensor assembly from step 3 was then manually pushed downward into the cylindrical ground tube using a flat piece of wood to distribute the load, with care taken not to strip the pieces of shim stock that were glued to the edges of the guard piece. The guard-sensor assembly stopped a short distance from complete insertion. After confirming with a Fluke multimeter that the guard and the ground were electrically insulated, a plastic ring was placed on top of the hemi-cylindrical guard and a rubber mallet was then used to drive it completely into the cylindrical ground tube. EP42HT-2FG MasterBond epoxy was then applied to all thin gaps between guard and ground using a small syringe. FIG. 15 illustrates this assembly with the plastic cap in place.
5. To make the electrical connection of the sensor strip to its sensor voltage, a threaded through-hole was drilled through the sensor strip such that the hole was of the size to hold a 0-80 316 stainless-steel screw. A multiple stand 24AWG electrical wire was soldered to a brass washer for #1 screw size (0.078″ ID and 0.156″ OD) as shown in FIG. 16(A). Then, super-glue was used to line the bottom of the brass washer with a nylon plastic washer for #1 screw size (0.084″ ID and 0.219″ OD), as shown in FIGS. 16(B) and 16(C). Finally, a 0-80 316 stainless-steel screw of ¼″ length was inserted through the washer into the sensor (FIG. 16(D)).
6. As illustrated in FIG. 17, a 0.875″ corrosion-resistant precision compression spring with 9.12 lbf/inch stiffness was inserted into the sensor boss. The stainless-steel adapter shown in FIG. 17 was then inserted to surround the spring such that the spring finally sat in the 0.7″ long cavity in the adaptor. The other end of the wire connected to the sensor in step 5 was soldered to the cup of the BNC wall mounted connector. The latter was then screwed into place by rotating the steel adapter piece counter-clockwise to avoid twisting the wire.
7. After the BNC connector was tightened flush with the front face of the adapter, a Delrin sleeve (as shown in FIG. 17(B)) was inserted to provide insulation between the adaptor, which carries the guard voltage due to the spring's contact with the back of the hemi-cylindrical guard surface, and the boss holding the adapter, which is held at the ground voltage identical to that of the rest of the cylindrical ground tube. The Delrin sleeve and the stainless-steel adaptor were pushed into place, tensioning the spring. A set screw was then inserted to the side of boss and tightened to hold the Delrin sleeve by friction against the inner diameter of the boss. This final assembly is depicted in FIG. 18.

### Design Constraints

To avoid stressing the processing electronics, spacings in each probe are set to maintain the capacitance between sensor and ground <800 pF and their mutual resistance >5 MΩ.

In addition, the capacitance between sensor and guard is kept <200 pF, including the high-quality coaxial cable that connects the probe to the processing electronics. Cable length must produce a resistance <100Ω in its central sensor wire and <2Ω in its outer braided guard. Accordingly, for each probe, adapters are designed to bring sensor and guard voltages to the inner wall surface without short-circuit, while maintaining uninterrupted contact with the processing electronics despite vibrations. Finally, both reference probe and prototype cylindrical Capacitance Level Detector are driven by the same clock but with two different pre-amps (as described in FIG. 2), and they are placed judiciously to minimize mutual interference.

When more than one probe is used in close proximity, such as the level sensor, and the reference probe below, it is important to avoid ‘cross-talk’, i.e., a beating interference of the two probes. Also, it is prudent to keep them away from one another by a distance at least equal to the length of the longest field line from sensor to ground. In our case, the level sensor has a longest field line of length roughly equal to the prototype cylindrical Capacitance Level Detector diameter. The reference probe is therefore prudently inserted below the grounded hemi-cylinder of the level sensor, thereby raising the distance from its own guard to the guard of the level sensor. (Alternatively, as indicated earlier, if it is acceptable to the user that multiplexing electronics interrogate the Capacitance Level Detector and the reference sensor separately, it is possible for the two probes to be located more closely and to share the same guard).

### Phase and Amplitude Measurements

Measurements of K′ₑ and K″ₑ require an accurate determination of the guard phase lead, which is not recorded precisely enough by oscilloscopes or conventional data acquisition systems. In turn, this determination relies on precise measurements of the amplitude V, mean value v̅ and frequency f of both clock and guard signals. Here, we show how to fit these quantities for any signal that is approximately sinusoidal [53]. We denote the phase of guard and clock with respect to the sampling origin by the respective symbols ϕ₀_{_{g}} and ϕ₀_{_{c}} to distinguish them from the guard phase lead ϕ=ϕ₀_{_{g}}−ϕ₀_{_{c}}.

For both clock and guard, we first fit the four quantities v̅, V, f and ϕ₀ simultaneously by minimizing the cost function (F):

F=Σᵢ₌₁^{N}^{ₐ}{v̅+V cos[τ(i)+ϕ₀]−v(i)}², (33)

where Nₐ is the number of acquired samples, τ(i)≡2π(i−1)/nₜ is a series of phases at discrete sampling times, v(i) is the corresponding voltage series, and nₜ≡v/f∈R is the real number of samples in a signal period 1/f acquired at the sampling rate v. Toward implementing a Newton-Raphson (NR) procedure, we calculate the partial derivatives

$${F}_{V}^{′} ≡ \frac{\partial F}{\partial V} = 2 {\sum }_{i = 1}^{{N}_{a}} cos [ τ ( i ) + {ϕ}_{0} ] {Δ v}_{i} , \qquad ( 34 )$$

where we define the shorthand:

$${Δ v}_{i} ≡ \{ \overline{v} + V cos [ τ ( i ) + {ϕ}_{0} ] - v ( i ) \} ; \qquad ( 35 )$$

$${F}_{V}^{″} ≡ \frac{{\partial }^{2} F}{\partial {V}^{2}} = 2 {\sum }_{i = 1}^{{N}_{a}} {cos}^{2} [ τ ( i ) + {ϕ}_{0} ] , \qquad ( 36 )$$

$${F}_{\overline{v}}^{′} ≡ \frac{\partial F}{\partial \overline{v}} = 2 {\sum }_{i = 1}^{{N}_{a}} {Δ v}_{i} , \qquad ( 37 )$$

$${F}_{\overline{v}}^{″} ≡ \frac{{\partial }^{2} F}{\partial {\overline{v}}^{2}} = 2 {N}_{a} , \qquad ( 38 )$$

$${F}_{{ϕ}_{0}}^{′} ≡ \frac{\partial F}{\partial {ϕ}_{0}} = - 2 V {\sum }_{i = 1}^{{N}_{a}} sin [ τ ( i ) + {ϕ}_{0} ] {Δ v}_{i} , \qquad ( 39 )$$

$$and$$

$${F}_{{ϕ}_{0}}^{″} \frac{{\partial }^{2} F}{\partial {ϕ}_{0}^{2}} = - 2 V {\sum }_{i = 1}^{{N}_{a}} \{ cos [ τ ( i ) + {ϕ}_{0} ] {Δ v}_{i} - V {sin}^{2} [ τ ( i ) + {ϕ}_{0} ] \} . \qquad ( 40 )$$

Because signal frequency f does not appear explicitly in Eq. (33), we find the best nₜ using the derivatives

$${F}_{{n}_{t}}^{′} ≡ \frac{\partial F}{\partial {n}_{t}} = \frac{4 πV}{{n}_{t}^{2}} {\sum }_{i = 1}^{{N}_{a}} sin [ τ ( i ) + {ϕ}_{0} ] {Δ v}_{i} , \qquad ( 41 )$$

$$and$$

$${F}_{{n}_{t}}^{″} ≡ \frac{{\partial }^{2} F}{\partial {n}_{t}^{2}} = \frac{8 πV}{{n}_{t}^{3}} {\sum }_{i = 1}^{{N}_{a}} i \{ - \frac{i π}{{n}_{t}} cos [ τ ( i ) + {ϕ}_{0} ] {Δ v}_{i} - sin [ τ ( i ) + {ϕ}_{0} ] {Δ v}_{i} + \frac{i π}{{n}_{t}} V {sin}^{2} [ τ ( i ) + {ϕ}_{0} ] \} . \qquad ( 42 )$$

Then, the NR finds the (j+1) iteration of the unknown roots in terms of the j-th using:

Vⱼ₊₁=Vⱼ−F′_{V}/F″_{V}, (43)

v̅_̅{̅J̅+̅1̅}̅=v̅_{J}−F′_{v̅}/F″_{v̅}, (44)

ϕ₀_{ⱼ₊₁}=ϕ₀_{ⱼ}−F′_{ϕ}_{₀}/F″_{ϕ}_{_{0′}}, (45)

and

nₜ_{ⱼ₊₁}=nₜ_{ⱼ}−F′ₙ_{ₜ}/F′ₙ_{_{t′}} (46)

where all derivative functions on the right-hand-side are evaluated at (Vⱼ, v̅ⱼ, ϕ₀_{ⱼ}, nₜ_{ⱼ}). Our experience is that best accuracy is achieved if the sampling window is as close to an exact multiple of the period 1/f of the clock or guard signals as possible.

We further exploit these estimates of mean voltages (v̅_̅{̅g̅}̅, v̅_̅{̅c̅}̅) and amplitudes (V_{g}, V_{c}) to search for the guard phase lead near φ≃ϕ₀_{_{g}}−ϕ₀_{_{c}} that minimizes the mean distance between measured normalized voltages [v*_{g}(i); v*_{c}(i)]≡[(v_{g}(i)−v̅_̅{̅g̅}̅)/V_{g}; (v_{c}(i)−v̅_{c})/V_{c}] and a Lissajous ellipse of unit amplitudes and phase (1). This is achieved by calculating:

Eᵢ≡[v*_{c}(i)²−2v*_{c}(i)v*_{g}(i)cos ϕ+v*_{g}(i)²−sin²ϕ]²; (47)

at each sample of index i and minimizing their sum over all Nₐ voltage samples,

F_{ϕ}(ϕ)≡Σᵢ₌₁^{N}^{ₐ}Eᵢ. (48)

To that end, we employ a NR procedure that seeks the root of:

$${F}_{ϕ}^{′} ≡ \frac{\partial {F}_{ϕ}}{\partial ϕ} = 4 {\sum }_{i = 1}^{{N}_{a}} [ {v}_{c}^{*} {v}_{g}^{*} - cos ϕ ] sin ϕ [ {v}_{c}^{* 2} + {v}_{g}^{* 2} - 2 {v}_{c}^{*} {v}_{g}^{*} cos ϕ - {sin}^{2} ϕ ] ; \qquad ( 49 )$$

starting with the estimate φ≃ϕ₀ (guard)−ϕ₀(clock) obtained earlier. This requires the second derivative (F″_{ϕ}):

$${F}_{ϕ}^{″} ≡ \frac{{\partial }^{2} {F}_{ϕ}}{\partial {ϕ}^{2}} = 4 {\sum }_{i = 1}^{{N}_{a}} [ {v}_{c}^{*} {v}_{g}^{*} cos ϕ - cos ( 2 ϕ ) ] [ {v}_{c}^{* 2} + {v}_{g}^{* 2} - 2 {v}_{c}^{*} {v}_{g}^{*} cos ϕ - {sin}^{2} ϕ ] + 2 {sin}^{2} {ϕ [ cos ϕ - {v}_{c}^{*} {v}_{g}^{*} ]}^{2} . \qquad ( 50 )$$

In Eqs. (49)-(50), v*_{c} and v*_{g} are samples of index i. The next iteration ϕⱼ₊₁ of the NR solution is found in terms of ϕⱼ using:

ϕⱼ₊₁=ϕⱼ−F′_{ϕ}(ϕⱼ)/F″_{ϕ}(ϕⱼ). (51)

For perfect noiseless sinusoidal signals, there exists two values of ϕ separated by π such that Eᵢ≡0, ∀i. More generally, because E is insensitive to the sign of ϕ, a drawback is that we cannot detect whether the clock leads the guard or vice-versa. In other words, if ϕ≡π±δ, because cos(π±δ)=−cos δ and sin²(π±δ)=(∓sin δ)²=sin² δ, then ± is not detectable by minimizing F_{ϕ}(j)) in Eq. (48). Because in some cases the processing electronics might bring the phase from below π to above π as Kₑ changes, an ambiguity can arise unless we distinguish the actual value of ϕ, not just its positive distance δ from π. Such ambiguity is lifted by observing the direction of rotation of the Lissajous ellipse. In this construction, time progresses in a clockwise (CW) rotation on the ellipse for 0<ϕ<π rad and counterclockwise (CCW) for π<ϕ<2 π rad. To find the rotation, voltages can be represented in the complex plane as v*_{c}=exp(ια) cos α+ι sin α and v*_{g}=exp[ι(α+ϕ)]. Because both signals are harmonic and sin≡α cos(α−π/2), their respective imaginary parts lag them by π/2 rad. In this case, imaginary parts of either harmonic signals sampled at index i can be reconstructed approximately from the corresponding samples at index i−I_{ϕ} that lag by one fourth of the whole period T, in a way similar to the “helical sequence” invoked in a Hilbert transform, as found in Bracewell, R. N. ‘The Fourier Transform and its Applications, 2^{nd} ed., pp. 267-271 (2008). Because sampling is discrete, I_{ϕ} can either be I_{ϕ}=I′_{ϕ}≡floor(nₜ/4) or I_{ϕ}=I″_{ϕ}≡ceil(nₜ/4). (Note that, with a finite number N_{α} of acquired samples, such construction can only be accomplished for samples with index I_{ϕ}+1≤i≤N_{α}). Normalized clock and guard can then be represented by the vectors [v*_{c}(i); v*_{c}(i−I_{ϕ})] and [v*_{g}(i); v*_{g}(i−I_{ϕ})] in the complex plane. The sign of their cross product (ω̅(i)):

ω̅(i)≡sign[v*_{c}(i)v*_{g}(i−I_{ϕ})−v*_{c}(i−I_{ϕ})v*_{g}(i)] (52)

determines whether the guard lags the clock by a phase ϕ<π rad (if ω̅(i)=+1) or by φ>π rad (if ω̅(i)=−1). However, because there is a finite number of samples in a π/2 rad angle increment, one cannot decide a priori between I′_{ϕ}=floor(nₜ/4) and I″_{ϕ}=ceil(nₜ/4). A simple remedy is to calculate ω̅′(i) for I′_{ϕ} and ω̅″(i) for I″_{ϕ}, ∀i∈[I″_{ϕ}, Nₐ], and to interpolate the result to a number ω̅(i)=ω̅′(i)+[ω̅″(i)−ω̅′(i)][I_{ϕ}−I′_{ϕ}]/[I″_{ϕ}−I′_{ϕ}], where ω̅(i)∈[−1, +1] and I_{ϕ}≡nₜ/4 is a rational number (no longer an integer). Then, the real number (ω̅):

$$ϖ = ( \frac{1}{{N}_{a} - {I}_{ϕ}^{″}} ) {\sum }_{i = {I}_{ϕ}^{″} + 1}^{{N}_{a}} ϖ ( i ) . \qquad ( 53 )$$

measures whether 0<ϕ<π rad (ω̅>0), or π<ϕ<2π rad (ω̅<0).

Finally, our experience is that phase determination can remain ambiguous if (I) is either near 0 or π rad. To avoid this, one can artificially rotate phase to the nearest π/2 rad if ω̅>0 (CW Lissajous rotation) or 3π/2 rad if ω̅<0 (CCW Lissajous rotation) by shifting the series of guard signal points. Once the algorithm determines the resulting artificial phase lead, it shifts it back to restore the true phase. To that end, if 0<<π rad (i.e. m>0), the algorithm calculates the distance Δ≡π/2−ϕ to bring the phase closest to π/2; if π≤ϕ<2π rad (i.e. ω̅<0), then it rotates the phase toward 3π/2 rad and defines Δ≡3π/2−ϕ. If Δ<0, the algorithm slides the guard sample points backward with respect to the clock by a positive integer number of samples δₛ. If instead Δ>0, then it shifts the guard ahead by a negative δₛ. In short,

$${δ}_{s} = floor ( \frac{- Δ}{2 π} \frac{v}{f} ) if Δ < 0 \qquad ( 54 )$$

$$and$$

$${δ}_{s} = - floor ( \frac{Δ}{2 π} \frac{v}{f} ) if Δ > 0.$$

Once the artificially-shifted phase is recorded, the true phase is restored as:

ϕₜᵣᵤₑ=ϕ_{shifted}+2πδₛ/nₜ, (55)

where nₜ v/f∈R and δₛ inherits its sign from Eq. (54). To avoid processing signals with a discontinuity, a trade-off of this technique is that the leading edge of both clock and guard must be truncated by a number |δₛ| of scans if Δ<0, whereas if Δ>0, the trailing edge is so truncated.

### Examples

### Integrated Reference Probe

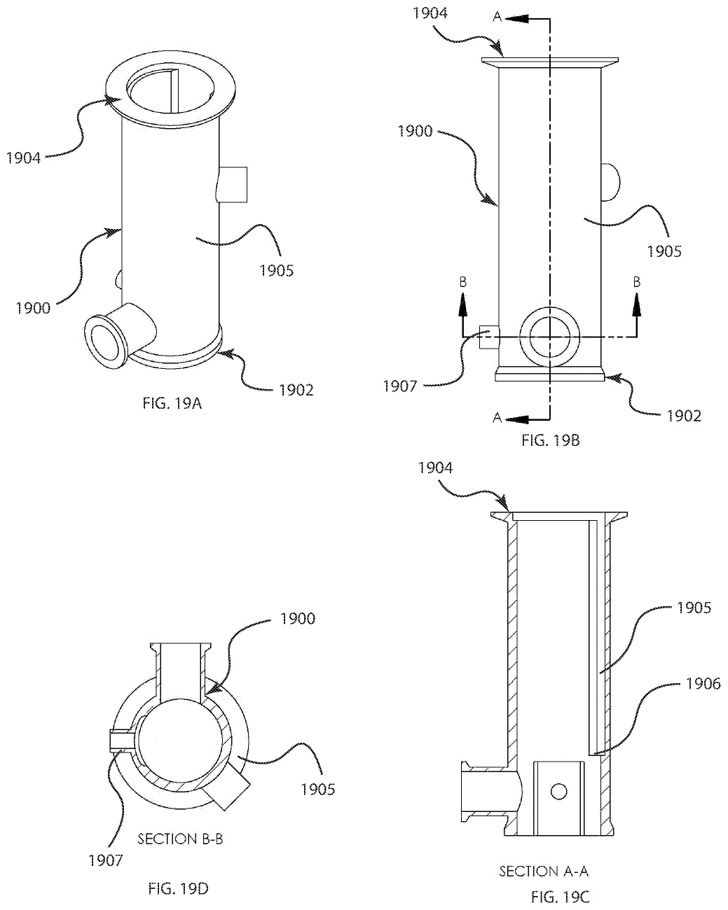

The use of a reference probe was previously described as well as its importance in monitoring Kₑ to account for changes in a powder, for example, due to absorption of moisture. FIG. 19A-D illustrates one example of a feed tube 1900 for accepting a reference probe, the tube 1900 extending between a proximal end 1902 and a distal end 1904. As shown in FIG. 19A, a substantially cylindrical vessel or tube 1900 includes a circumferential sidewall 1905. Tube 1900 may further include a cylindrical boss 1907 located adjacent proximal end 1902 (FIG. 19B). In at least some examples, boss 1907 has an inner diameter of approximately 0.5313″. Additionally, a portion of sidewall 1905 may be removed (e.g., through milling or other suitable methods) to form a cutout 1906 adjacent proximal end 1902 (FIG. 19C), the cutout being sized and shaped to receive a curved reference guard plate 1930 adjacent boss 1907.

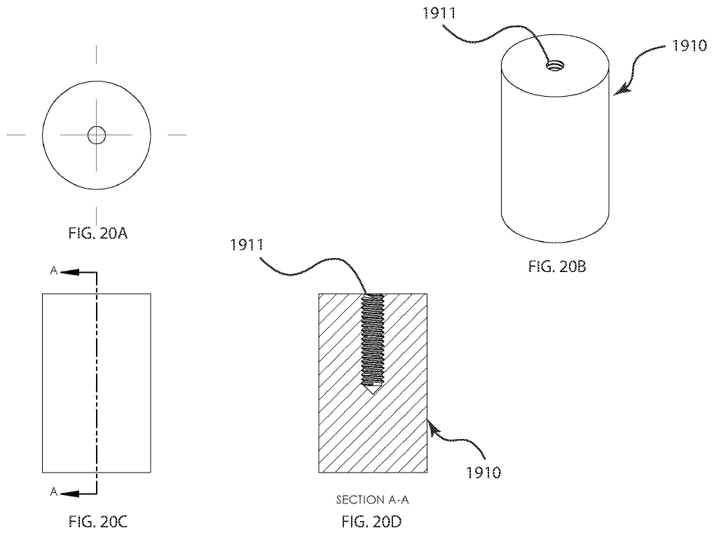

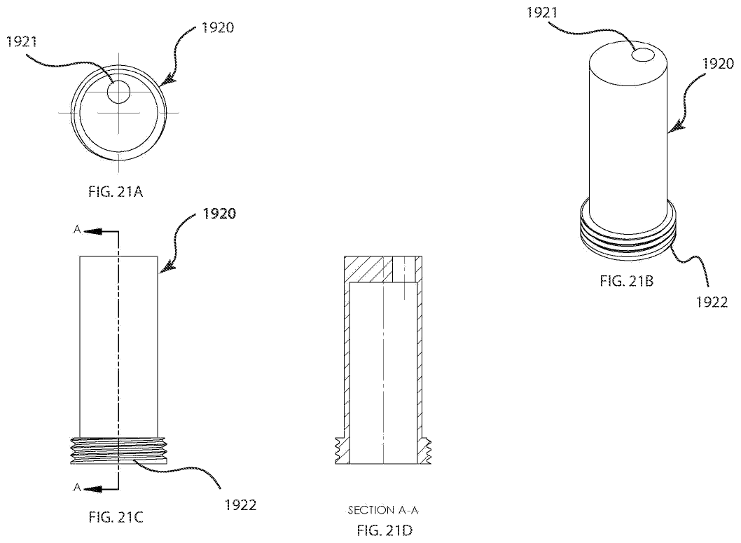

A generally cylindrical reference sensor 1910 may be concentrically placed within a metallic cup 1920 (FIGS. 20A-D and 21A-D). Sensor 1910 may be formed of a suitable conductive metal, such as stainless steel, brass, or aluminum, and may have a central aperture 1911 to facilitate electrical coupling with other components. Sensor 1920 may be placed within a cup 1920, the cup having an off-axis aperture 1921 on a first end, and a threaded connection 1922 at a second end. A cylindrical Delrin sleeve (not shown) of 0.9″ height, 0.391″ ID and 0.5″ OD may be fitted over the reference cup to isolate it from the grounded boss 1907 that will hold the assembled probe. In at least some examples, the outer diameter of cup 1920 may be selected to fit within boss 1907 of tube 1900.

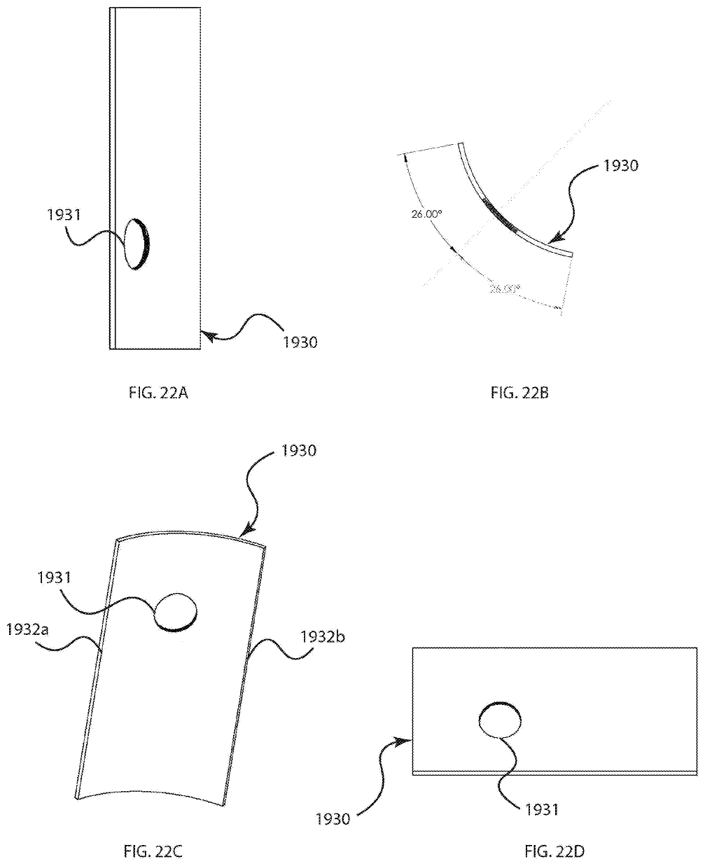

A curved reference guard 1930 formed of a suitable conductive metal such as stainless steel, brass or aluminum may be inserted into the cutout 1906 of tube 1900, the reference guard 1930 having the same or substantially similar radius of curvature as the tube 1900 (FIGS. 22A-D). Reference guard 1930 may also include a threaded port 1931 configured and arranged to mate with threaded connection 1922 of cup 1920. In some examples, the reference guard forms an arc with angular sector adjusted to produce a capacitance similar to that of the Capacitance Level Detector, as provided in Equations (1), (17-18) and (26). Nearly matching the capacitances of the Capacitance Level Detector and reference probe ensures that their signals have similar detection limits, thereby optimizing measurement accuracy of the level and/or mass of material in the vessel. In some examples, port 1931 is disposed approximately halfway between the side edges 1932a,1932b of reference guard 1930 as shown. Specifically, port 1931 may be formed so that it that aligns with boss 1907 when the reference guard 1930 is placed in its intended location within tube 1900.

### Example 1: Assembly of Reference Probe

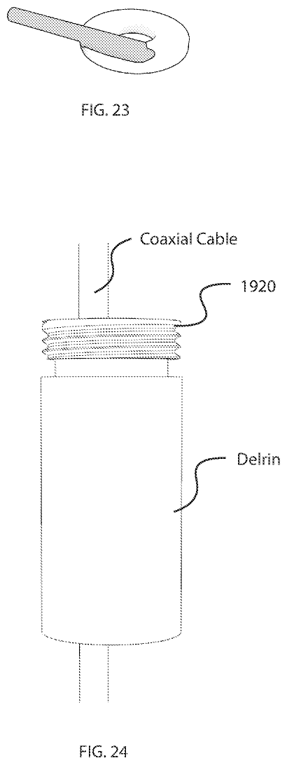

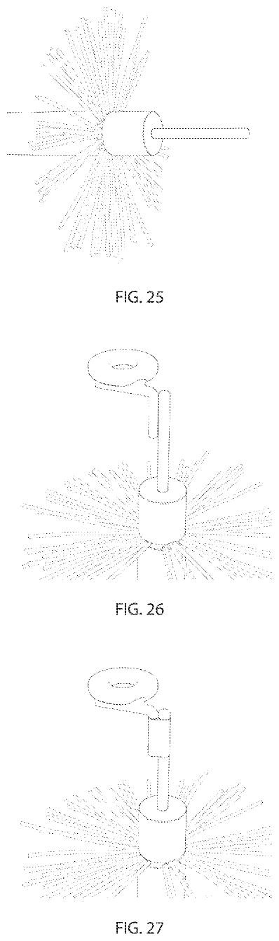

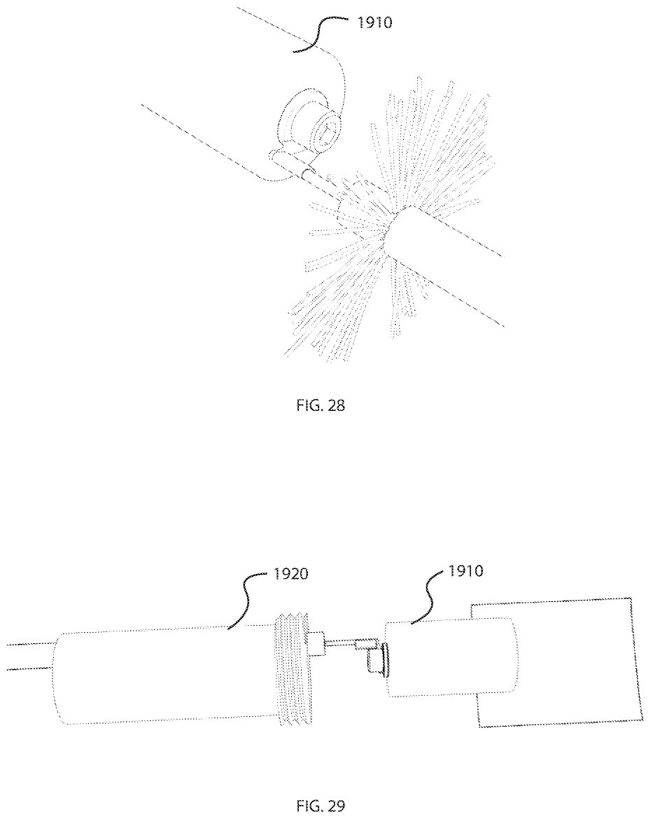

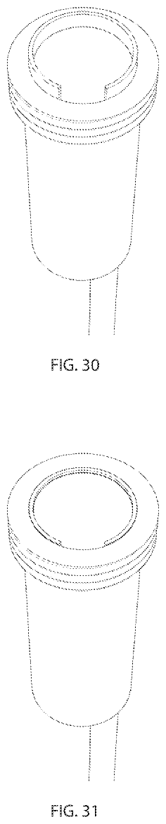

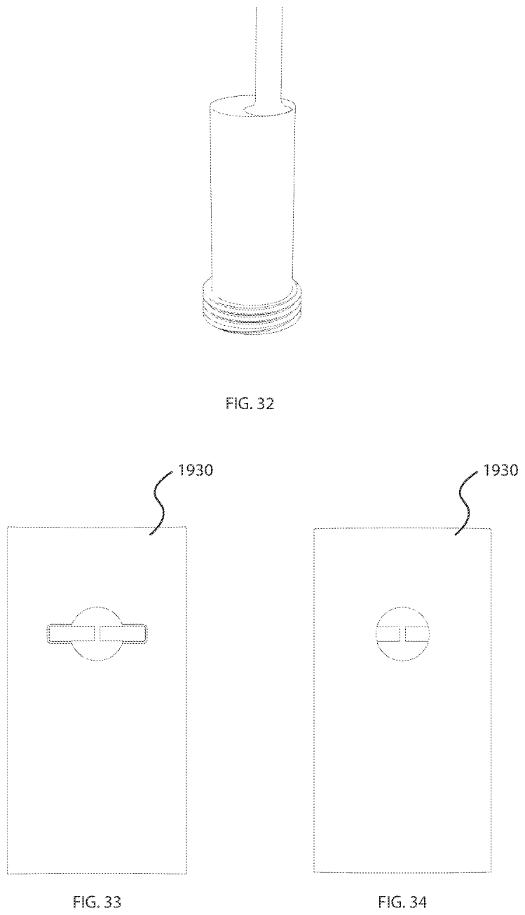

One example of a method of assembling a reference probe will now be described:
1. A piece of resistor wire of approximately ½ inch is first soldered on a brass washer for number 1 screw size, 0.078″ ID, 0.156″ OD and bent (FIG. 23). The washer may be held on the sensor cylinder by a brass socket head screw, 0-80 thread size, ⅛″ long, and the resistor wire will be soldered to the inner conductor of the coaxial cable as will be described below.
2. A piece of EC-DM-L2-5 high-quality coaxial cable of 1 m length (made by Capacitec) may be attached to a male BNC connector and cut sharply at its other end. The latter is inserted through the Delrin sleeve and then through the aperture 1921 of cup 1920 (FIG. 24).
3. The two outer guarded braids of the EC-DM-L2-5 high-quality coaxial cable are stripped bare with a razor blade. Particular care is made to remove the black graphite guarded conductors separating the metal braids. The guarded braids are swept back to expose a 0.75″ length of inner sensor wire protected by its plastic sheath. This sheath is partially removed to expose a ⅛″ length of bare inner sensor wire. The guarded braids are trimmed to a ¼″ length and co-mingle (FIG. 25).
4. A ⅛″-long piece of 3/16″ shrink tubing is inserted over the sensor wire sheath before the wire is soldered on the resistor wire of step 1. The shrink tubing is then moved to cover the wire and provide electrical isolation all the way to the washer (FIGS. 26-27).
5. The 0-80 screw mentioned in step 1 is passed through the washer and threaded into the sensor 1910, thereby bonding the sensor wire and its sheath to the sensor 1910 (FIG. 28).
6. A piece of 0.0125″-inch shim stock is cut to match the height and circumference of the sensor 1910. It is wrapped around the sensor cylinder, while the cylinder is pushed into the cavity of the cup 1920 (FIG. 29). Particular care is paid to pull the EC-DM-L2-5 high-quality coaxial cable out of the hole of the cup as the sensor cylinder is inserted, to avoid straining the cable. Upon drawing the coaxial cable out of the hole, the braided guard makes contact with the hole, thereby bringing the cup to the guard voltage. In this operation, the cavity of the cup shown is large enough to accommodate the sensor wire and the bent resistor wire to which it is attached. The piece of shim stock holds the sensor cylinder in the guarded cup by friction, and isolates them electrically from one another.
7. Excess shim stock is sheared from the front face of the assembly using a razor blade (FIG. 30). The assembly is then held face-up in a vice. EP42HT-2FG MASTERBOND™ epoxy is poured into the thin gap between the shim stock and the metal parts to bond them (FIG. 31).
8. Once the epoxy is cured, the assembly is held upside down in a vice and EP42HT-2FG MASTERBOND™ epoxy is placed around the coaxial cable to provide strain relief once cured (FIG. 32).
9. Strips of woven chemical-resistant plastic mesh with opening size 0.0165″ are superglued in the periphery of the back of the curved guard plate 1930.
10. The probe is inserted through the boss 1907 of feed tube 1900, and threaded into the curved guard plate 1930.

The resulting assembly is retracted to put the guard in its recess of the feed tube. The feed tube is placed upside down to pour EP42HT-2FG MASTERBOND™ epoxy. Dams made of thin shim stock prevent epoxy from oozing out during cure, and to invade the thread linking the guard cup and curved guard plate, so these can be disassembled for future cleaning.

### Example 2: Assembly of Reference Probe

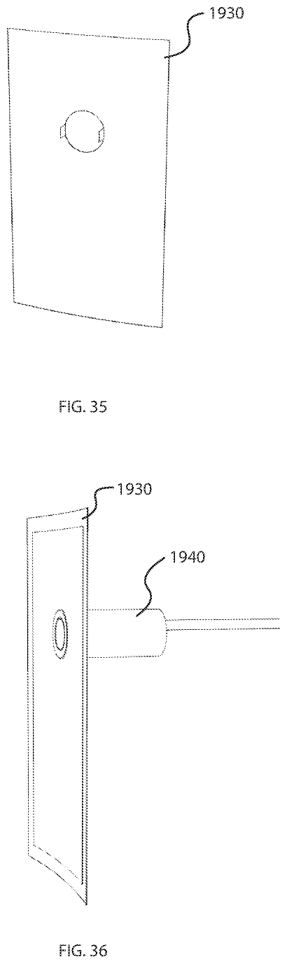

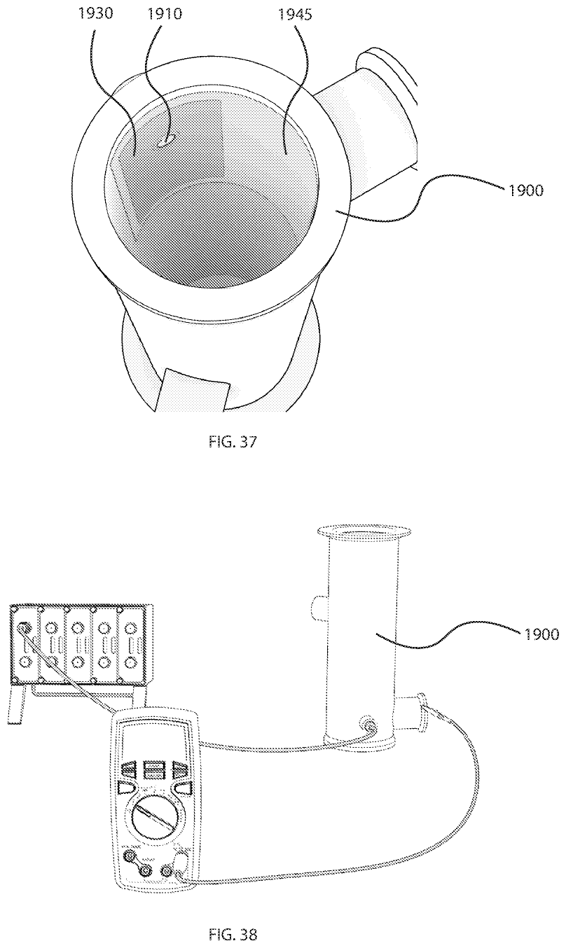

In another design, the solid curved guard plate was replaced with a piece of brass shim stock of the same dimensions, and brass, rather than stainless steel, was selected as the material for the adapter pieces (e.g., the sensor and cup). Lastly, because there was no solid curved guard plate to fasten that simpler adapter, the outer surface of the latter was not threaded. In this second example, assembly is identical to steps 1-8 of example 1 above. The instant method differs in the following:
9. A brass plate of 0.002″ is cut to the size of the guard and punched with a hole slightly larger than the diameter of the cup to form guard plate 1930. Small ‘ears’ are soldered and cut as shown in the pictures below (FIG. 33-34).
10. The guard plate 1930 is lined with a piece of 0.002″-thick plastic shim stock using superglue. Ears are bent up through the hole above the shim. The shim will provide electrical isolation of the guarded brass plate from the grounded wall once introduced in the feed tube in step 12 (FIG. 35).
11. A piece of shrink tubing is inserted over the adapter 1940 assembled in step 8. The adapter is then introduced between the ears through the hole in the guard shim plate. The shrink tubing is slid over the ears and heated for a tight fit. Once shrunk, it binds the plate and adapter tightly through the ears (FIG. 36).
12. The probe with sensor 1910 is inserted through the boss of the feed tube 1900 and the guarded brass plate 1930 is bent into place and affixed with tape 1945 (FIG. 37).
13. Finally, the reference probe is tested along with the level detector in the feed tube 1900 (FIG. 38).

### Reference Probe Arrangements

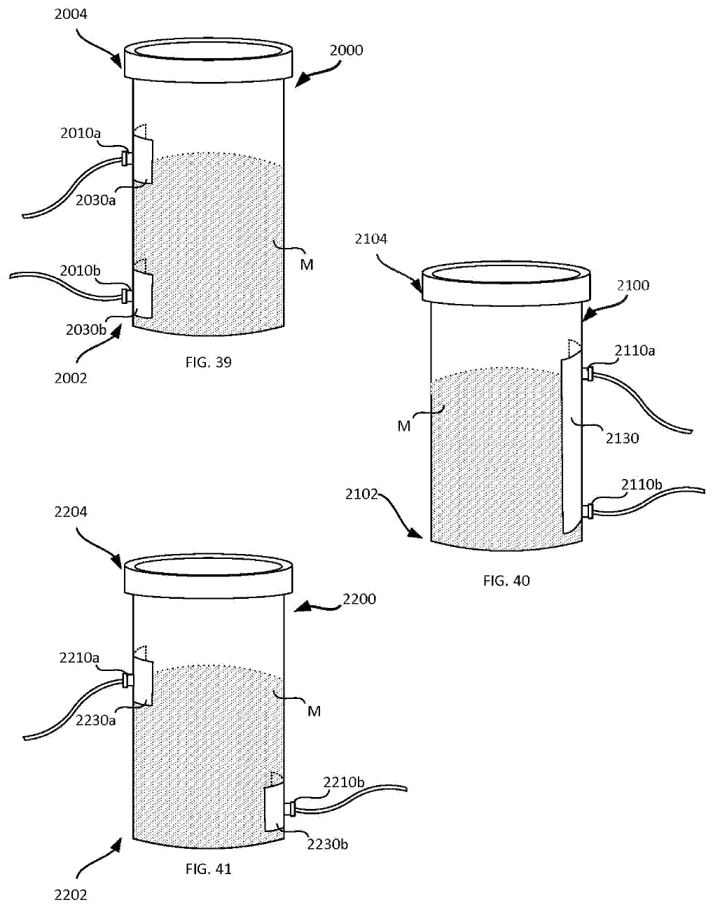

FIGS. 39-41 are schematic perspective views of several examples of tubes having reference probes. In FIG. 39, tube 2000 is generally cylindrical and extends between a proximal end 2002 and a distal end 2004. A bulk material “M” is disposed inside the cylindrical tube. A first probe 2010a is disposed adjacent distal end 2004 and includes a designated curved first guard surface 2030a. A second probe 2010b is disposed adjacent proximal end 2002 and includes a designated second guard surface 2030b. In this example, first and second guard surfaces 2030a-b are approximately equal in size and shape, and the two guard surfaces are spaced from one another. Additionally, the two probes 2010a,2010b are disposed on a same side of the tube 2000. In this example, first probe may serve as a capacitance level detector as described above, and second probe may serve as a reference probe to continuous measure dielectric properties of a material within tube 2000.

In FIG. 40, tube 2100 is generally cylindrical and extends between a proximal end 2102 and a distal end 2104. A first probe 2110a is disposed adjacent distal end 2004 and a second probe 2110b is disposed adjacent proximal end 2102. A single curved guard 2130 is disposed along the sidewalls of tube 2100, the guard serving as a common guard for both probes.

In FIG. 41, tube 2200 is generally cylindrical and extends between a proximal end 2202 and a distal end 2204. A first probe 2210a is disposed adjacent distal end 2204 and a second probe 2210b is disposed adjacent proximal end 2202. Each of the two probes has a corresponding guard 2230a,2230b. In this example, the two probes are diametrically opposed to one another on opposite sides of the tube. That is, the two probes are disposed 180 degrees apart along the circumference of tube 2200. It will be understood that other variations are also possible, and that the three examples shown are to be taken as illustrative and not limiting.

The present invention is not to be limited by the specific embodiments disclosed in the examples that are intended as illustrations of a few aspects of the invention and any embodiments that are functionally equivalent are within the scope of this invention. Indeed, various modifications of the invention in addition to those shown and described herein will become apparent to those skilled in the art and are intended to fall within the scope of the appended claims.

A number of references have been cited herein, the entire disclosures of which are incorporated herein by reference.

1. A Capacitance Level Detector useful for the continuous and non-invasive measurement of the level and/or mass of a non-conductive or weakly-conductive bulk material in a vessel, while said bulk material is inside the vessel, and wherein the measurement is taken inside the vessel, and wherein the instrument produces level and/or mass as continuous functions of time and amount of said bulk material inside the vessel.

2. The Capacitance Level Detector of claim 1, wherein the vessel acts as the Capacitance Level Detector and the vessel comprises a sensor, an electrically insulated guard surface surrounding the sensor, and an electrically insulated ground surface.

3. A method for the continuous and non-invasive measurement of the level and/or mass of a non-conductive or weakly-conductive bulk material in a vessel, wherein the vessel comprises a sensor, an electrically insulated guard surface surrounding the sensor, and an electrically insulated ground surface, and wherein the method comprises the steps of:
a) introducing the non-conductive or weakly-conductive bulk material into the vessel;
b) continuously measuring the voltage between the electrically insulated guard surface while said bulk material is inside the vessel; and
c) correlating the voltage measurements to the level and/or mass of said bulk material, while said bulk material resides in the vessel at the time of said measurements.

4. The method of claim 3, wherein the non-conductive or weakly-conductive bulk material is static inside the vessel.

5. The method of claim 3, wherein the non-conductive or weakly-conductive bulk material is flowing through the inside of the vessel.

6. The method of claim 3, wherein the vessel is a tube of concave cross-section, wherein the electrically insulated guard surface and the electrically insulated ground surface form parts of the tube wall, and wherein the sensor is attached to the inside surface of the tube wall comprising the electrically insulated guard surface.

7. (canceled)

8. (canceled)

9. (canceled)

10. The method of any of claim 6, wherein the sensor is a conductor that is attached to the inside surface of the tube and is connected to processing electronics by one or more inner conductors, wherein the one or more inner conductors reside inside a coaxial cable surrounded by one or more outer conductors held at the guard voltage, and wherein the processing electronics reside outside the vessel.

11. (canceled)

12. The method of claim 3, wherein the non-conductive or weakly-conductive bulk material is a powder or a dielectric fluid.

13. (canceled)

14. (canceled)

15. (canceled)

16. (canceled)

17. (canceled)

18. (canceled)

19. (canceled)

20. (canceled)

21. A vessel comprising:
a body having a sidewall;
a first probe including a first sensor, an electrically insulated first guard surface surrounding the first sensor, and an electrically insulated ground surface; and
a second probe including a second sensor disposed away from the first sensor.

22. The vessel of claim 21, wherein the body is generally cylindrical and includes a proximal end and a distal end, and wherein the second probe is disposed adjacent the proximal end perpendicular to a longitudinal axis of the body, and further comprising a second guard surface that is concave and disposed adjacent the second sensor.

23. (canceled)

24. (canceled)

25. The vessel of claim 21, wherein the second guard surface at least partially extends along a circumference of the body.

26. The vessel of claim 21, wherein the first probe is disposed adjacent a distal end of the body and the second probe is disposed adjacent a proximal end of the body.

27. The vessel of claim 21, wherein the first guard surface is disposed adjacent both the first sensor and the second sensor and forms a common guard for the first and second sensors.

28. The vessel of claim 21, wherein the first guard surface and the second guard surface are spaced apart from one another.

29. The vessel of claim 21, further comprising a metallic cup having a threaded connection, wherein the second sensor is disposed within the metallic cup.

30. The vessel of claim 21, wherein the second probe is a non-invasive reference capacitance detector configured and arranged to continuously record the dielectric properties of a non-conductive or weakly-conductive bulk material in the vessel as continuous functions of time and amount of the bulk material inside the vessel.

31. The vessel of claim 21, wherein the second probe is configured and arranged to measure dielectric properties of a bulk material to evaluate the level and/or mass of the bulk material inside the vessel.

32. (canceled)

33. A method of measuring a level and/or mass of a non-conductive or weakly-conductive bulk material in a vessel comprising:
providing a vessel having a body, a first probe including a first sensor, an electrically insulated first guard surface and an electrically insulated first ground surface, and a second probe including a second sensor spaced from the first sensor;
introducing the non-conductive or weakly-conductive bulk material into the body;
continuously measuring the voltage between the first sensor and the electrically insulated first ground surface while the bulk material is inside the vessel; and
continuously measuring the voltage between the second sensor and the electrically insulated ground surface; and
correlating the voltage measurements of the first sensor and the voltage measurements of the second sensor to the level and/or mass of said bulk material, while the bulk material resides in the vessel at the time of the measurements, and while the bulk material may change its dielectric properties continuously with time.

34. (canceled)

35. (canceled)

36. (canceled)

37. (canceled)

38. (canceled)

39. (canceled)

40. (canceled)

41. (canceled)

42. (canceled)

43. (canceled)

44. A method of manufacturing a pharmaceutical product, comprising:
measuring a level and/or mass of a non-conductive or weakly-conductive bulk material in a vessel according to claim 33; and
adjusting a parameter in the manufacturing process based on the measured level and/or mass.

45. The method of claim 44, wherein adjusting a parameter comprises adjusting a speed of a motor.
